(19) United States
(12) Patent Application Publication
(10) Pub. No.: US 2023/0345775 A1
(43) Pub. Date: Oct. 26, 2023

(54) DISPLAY DEVICE

(71) Applicant: Samsung Display Co., LTD., Yongin-si (KR)

(72) Inventors: Hyeon Jun LEE, Yongin-si (KR); Chul KIM, Yongin-si (KR); Gyeong Ub MOON, Yongin-si (KR); Jong Yeop AN, Yongin-si (KR); Bo Ram CHOI, Yongin-si (KR)

(21) Appl. No.: 18/152,046

(22) Filed: Jan. 9, 2023

(30) Foreign Application Priority Data
Apr. 25, 2022 (KR) 10-2022-0050880

(51) Int. Cl. H10K 59/13; G06V 40/13; H10K 59/35; H10K 59/60

(52) U.S. Cl. CPC H10K 59/13; G06V 40/1318; H10K 59/351; H10K 59/353; H10K 59/60

(57) ABSTRACT

A display device includes: a first area including a plurality of first pixels; a second area adjacent to the first area, and including a plurality of second pixels; a first photo sensor adjacent to the plurality of first pixels at the first area, and to sense light; and a second photo sensor adjacent to the plurality of second pixels at the second area, and to sense light. A size of an area of the second photo sensor is different from a size of an area of the first photo sensor.

### CROSS-REFERENCE TO RELATED APPLICATION

This application claims priority to and the benefit of Korean Patent Application No. 10-2022-0050880, filed on Apr. 25, 2022, in the Korean Intellectual Property Office, the entire disclosure of which is incorporated by reference herein.

### BACKGROUND

### 1. Field

Aspects of embodiments of the present disclosure relate to a display device.

### 2. Description of the Related Art

As information-oriented society evolves, various demands for display devices are ever increasing. For example, display devices are being employed by a variety of electronic devices, such as smart phones, digital cameras, laptop computers, navigation devices, and smart televisions. Display devices may be flat panel display devices, such as a liquid-crystal display device, a field emission display device, and an organic light-emitting display device.

As privacy information is stored in portable electronic devices, fingerprint authentication has been used to verify a user’s fingerprint, which is biometric information of the user, in order to protect such privacy information. For example, the display device may authenticate a user’s fingerprint by optical sensing, ultrasonic sensing, capacitive sensing, and/or the like. The optical sensing may authenticate a user’s fingerprint by sensing light reflected from the user’s fingerprint. The display device may include a display panel including a plurality of pixels for displaying images, and photo sensors for sensing light in order to optically authenticate a user’s fingerprint.

The above information disclosed in this Background section is for enhancement of understanding of the background of the present disclosure, and therefore, it may contain information that does not constitute prior art.

### SUMMARY

Recently, as the healthcare industry emerges with great prospects, methods for more conveniently acquiring various biometric information related to health are being developed. For example, an optical blood-pressure measuring device may include a display panel including a plurality of pixels for displaying images, a pressure sensor for measuring pressure, and photo sensors for sensing light in order to measure a user’s blood pressure.

Aspects of one or more embodiments of the present disclosure are directed to a display device capable of both detecting a fingerprint and measuring blood pressure.

However, the present disclosure is not limited to the above aspects and features, and the above and other aspects and features of the present disclosure will be more apparent to those skilled in the art from the following description, or may be learned by practicing one or more of the presented embodiments of the present disclosure.

According to one or more embodiments of the present disclosure, a display device includes: a first area including a plurality of first pixels; a second area adjacent to the first area, and including a plurality of second pixels; a first photo sensor adjacent to the plurality of first pixels at the first area, and configured to sense light; and a second photo sensor adjacent to the plurality of second pixels at the second area, and configured to sense light. A size of an area of the second photo sensor is different from a size of an area of the first photo sensor.

In an embodiment, the size of the area of the second photo sensor may be larger than the size of the area of the first photo sensor.

In an embodiment, the size of the area of the second photo sensor may be greater than or equal to 1.5 times the size of the area of the first photo sensor.

In an embodiment, the plurality of first pixels may include: a first first sub-pixel configured to emit light of a first color; a second first sub-pixel adjacent to the first first sub-pixel in a first direction, and configured to emit light of a second color; a third first sub-pixel adjacent to the second first sub-pixel in a second direction crossing the first direction, and configured to emit light of a third color; and a fourth first sub-pixel adjacent to the first first sub-pixel in the second direction, adjacent to the third first sub-pixel in the first direction, and configured to emit light of the second color. The first photo sensor may be adjacent to the first first sub-pixel in a first diagonal direction crossing the first direction and the second direction.

In an embodiment, the plurality of second pixels may include: a first second sub-pixel configured to emit light of the first color; a second second sub-pixel adjacent to the first second sub-pixel in the first direction, and configured to emit light of the second color; a third second sub-pixel adjacent to the second second sub-pixel in the second direction, and configured to emit light of the third color; and a fourth second sub-pixel adjacent to the first second sub-pixel in the second direction, adjacent to the third second sub-pixel in the first direction, and configured to emit light of the second color. The second photo sensor may be adjacent to the first second sub-pixel in the first diagonal direction.

In an embodiment, each of the plurality of first pixels and the plurality of second pixels may include a first sub-pixel, a second sub-pixel, a third sub-pixel, and a fourth sub-pixel.

In an embodiment, the first sub-pixel may be configured to emit red light; the second sub-pixel and the fourth sub-pixel may be configured to emit green light; and the third sub-pixel may be configured to emit blue light.

In an embodiment, the first sub-pixel and the third sub-pixel may be alternately located along a first direction, the second sub-pixel and the fourth sub-pixel may be alternately located along the first direction, and the first sub-pixel and the second sub-pixel may be alternately located along a second direction crossing the first direction. A maximum luminance of one of the plurality of second pixels may be greater than a maximum luminance of one of the plurality of first pixels.

In an embodiment, the maximum luminance of the one of the plurality of second pixels may be greater than or equal to 1.5 times and less than or equal to 3 times the maximum luminance of the one of the plurality of first pixels.

In an embodiment, a size of an area of the first sub-pixel of the plurality of second pixels may be larger than a size of an area of the first sub-pixel of the plurality of first pixels.

In an embodiment, a thickness of an emissive layer of the first sub-pixel of the plurality of second pixels may be larger than a thickness of an emissive layer of the first sub-pixel of the plurality of first pixels.

In an embodiment, an emissive layer of the first sub-pixel of the plurality of second pixels may include a first luminous material, and an emissive layer of the first sub-pixel of the plurality of first pixels may include a second luminous material. The first luminous material may have a higher luminous efficiency than that of the second luminous material.

In an embodiment, the second luminous material may have a higher color gamut than that of the first luminous material.

In an embodiment, the second area may be surrounded by the first area.

In an embodiment, the plurality of second pixels may include: a first second sub-pixel configured to emit light of the first color; a second second sub-pixel adjacent to the first second sub-pixel in the first direction, and configured to emit light of the second color; and a third second sub-pixel adjacent to the second second sub-pixel in the second direction, and configured to emit light of the third color. The second photo sensor may be adjacent to the first second sub-pixel in the second direction, and adjacent to the third second sub-pixel in the first direction.

In an embodiment, a maximum luminance of one of the plurality of second pixels may be greater than a maximum luminance of one of the plurality of first pixels.

According to one or more embodiments of the present disclosure, a display device includes: a substrate; light-receiving electrodes spaced from one another on the substrate; pixel electrodes spaced from one another on the substrate, and spaced from the light-receiving electrodes; a first emissive layer on a first pixel electrode from among the pixel electrodes; a second emissive layer on a second pixel electrode from among the pixel electrodes; a first photoelectric conversion layer on a first light-receiving electrode from among the light-receiving electrodes, and adjacent to the first emissive layer; and a second photoelectric conversion layer on a second light-receiving electrode from among the light-receiving electrodes. A width of the second photoelectric conversion layer is different from a width of the first photoelectric conversion layer.

In an embodiment, the second emissive layer may be located closer to the second photoelectric conversion layer than the first photoelectric conversion layer, and the first emissive layer may be located closer to the first photoelectric conversion layer than the second photoelectric conversion layer.

In an embodiment, a maximum emission luminance of the second emissive layer may be greater than that of the first emissive layer.

In an embodiment, a width of the first emissive layer may be greater than a width of the second emissive layer.

According to one or more embodiments of the present disclosure, different kinds of photo sensors may be formed at (e.g., in or on) different areas, respectively, for example, such as at a first area and a second area of a display panel of a display device, so that the display device may be configured for fingerprint detection, as well as for blood pressure measurement.

However, the present disclosure is not limited to the above aspects and features, and the above and other aspects and features of the present disclosure will be more apparent to those skilled in the art from the following detailed description with reference to the drawings, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, nonlimiting embodiments with reference to the accompanying drawings, in which:

FIG. 1 is a plan view of a display device according to an embodiment of the present disclosure;

FIG. 2 is a block diagram of a display device according to an embodiment of the present disclosure;

FIG. 3 is a plan view showing areas of a display device according to an embodiment of the present disclosure;

FIG. 4 is a cross-sectional view showing a fingerprint detection in a first area according to an embodiment;

FIG. 5 is a cross-sectional view showing blood-pressure measurement in a second area according to an embodiment;

FIG. 6 is a graph showing pressure measurement values verse pressing time;

FIG. 7 is a graph showing a pulse wave signal versus pressing time;

FIG. 8 is a graph showing a pulse wave signal versus pressure;

FIG. 9 is a plan view showing a layout of pixels and photo sensors of a display panel according to an embodiment;

FIG. 10 is a plan view showing a layout of pixels and photo sensors of a display panel according to another embodiment of the present disclosure;

FIG. 11 is a plan view illustrating shapes of photo sensors;

FIG. 12 is a cross-sectional view of pixels and photo sensors according to an embodiment;

FIG. 13 is a plan view showing a layout of pixels and photo sensors of a display panel according to another embodiment of the present disclosure;

FIG. 14 is a plan view illustrating shapes of pixels according to another embodiment;

FIG. 15 illustrates cross-sectional views of pixels according to another embodiment;

FIG. 16 is a plan view showing a layout of pixels and photo sensors of a display panel according to another embodiment of the present disclosure;

FIG. 17 is a plan view showing a layout of pixels and photo sensors of a display panel according to another embodiment of the present disclosure; and

FIGS. 18-19 are plan views showing areas of a display device according to one or more embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

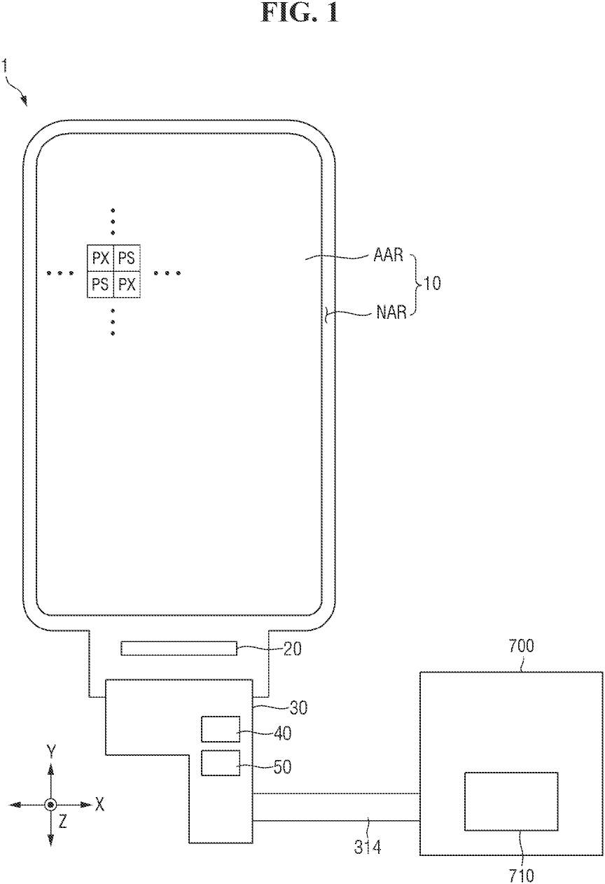

FIG. 1 is a plan view of a display device according to an embodiment of the present disclosure.

Referring to FIG. 1, the display device 1 may include a variety of suitable electronic devices that provide a display screen. Examples of the display device 1 include, but are not limited to, a mobile phone, a smart phone, a tablet PC, a mobile communications terminal, an electronic organizer, an e-book, a personal digital assistant (PDA), a portable multimedia player (PMP), a navigation device, an ultra mobile PC (UMPC), a television set, a game machine, a wristwatch-type electronic device, a head-mounted display, a personal computer monitor, a laptop computer, a vehicle instrument cluster, a digital camera, a camcorder, an outdoor billboard, an electronic billboard, various suitable medical apparatuses, various suitable inspection devices, various suitable home appliances including a display area, such as a refrigerator and a laundry machine, Internet of things (IoT) devices, and/or the like. Examples of the display device 1 described in more detail below include, but are not limited to, a smartphone, a tablet PC, a laptop computer, and/or the like.

The display device 1 may include a display panel 10, a display driver 20, a circuit board 30, a light-sensing circuit 50, a pressure-sensing circuit 40, a main circuit board 700, and a main processor 710.

The display panel 10 may include an active area AAR and a non-active area NAR.

The active area AAR includes a display area where images are displayed. The active area AAR may completely overlap with the display area. A plurality of pixels PX may be disposed at (e.g., in or on) the display area for displaying images. Each of the pixels PX may include a light-emitting unit (e.g., a light-emitting element) that emits light.

The active area AAR further includes a photo sensing area. The photo sensing area is a photosensitive area that senses an amount of incident light, a wavelength of incident light, and/or the like. The photo sensing area may overlap with the display area. According to an embodiment of the present disclosure, the photo sensing area may completely overlap with the active area AAR when viewed from the top (e.g., in a plan view). In this case, the photo sensing area may be the same or substantially the same as (e.g., may be identical to) the display area. According to another embodiment, the photo sensing area may be disposed only at (e.g., in or on) a part of the active area AAR. For example, the photo sensing area may be disposed only at (e.g., in or on) a limited area that is used for fingerprint recognition. In this case, the photo sensing area may overlap with a part of the display area DA, but may not overlap with another part of the display area.

A plurality of photo sensors PS that responds to light may be disposed at (e.g., in or on) the photo sensing area.

The non-active area NAR may surround (e.g., around a periphery of) the active area AAR. The display driver 20 may be disposed at (e.g., in or on) the non-active area NAR. The display driver 20 may drive the plurality of pixels PX and/or the plurality of photo sensors PS. The display driver 20 may output signals and voltages for driving the display panel 10. The display driver 20 may be implemented as an integrated circuit (IC), and may be mounted on the display panel 10. Signal lines for transferring signals between the display driver 20 and the active area AAR may be further disposed at (e.g., in or on) the non-active area NAR. As another example, the display driver 20 may be mounted on the circuit board 30.

The circuit board 30 may be attached to one end of the display panel 10 using an anisotropic conductive film (ACF). Lead lines of the circuit board 30 may be electrically connected to pads of the display panel 10. The circuit board 30 may be a flexible printed circuit board (FPCB), or a flexible film such as a chip-on-film (COF).

The light-sensing circuit 50 may be disposed on the circuit board 30. The light-sensing circuit 50 may be implemented as an integrated circuit (IC), and may be attached to the upper surface of the circuit board 30. The light-sensing circuit 50 may be connected to a display layer of the display panel 10. The light-sensing circuit 50 may sense a photo current generated by photo charges incident on the plurality of photo sensors PS of the display panel 10. The light-sensing circuit 50 may recognize a user’s pulse waves based on the photo current.

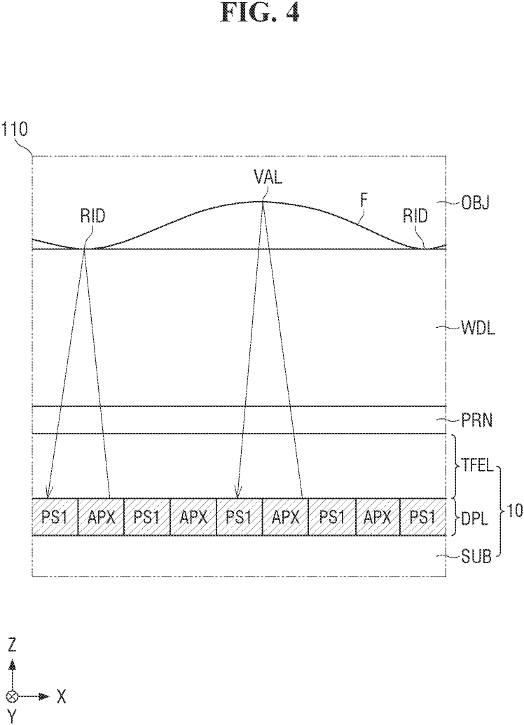

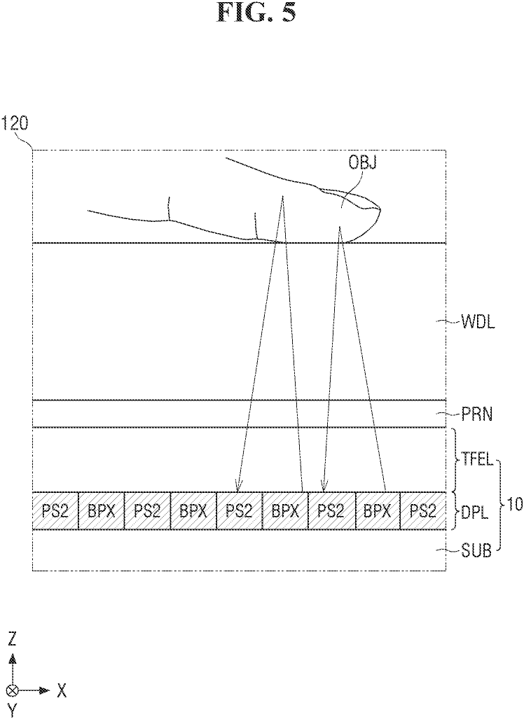

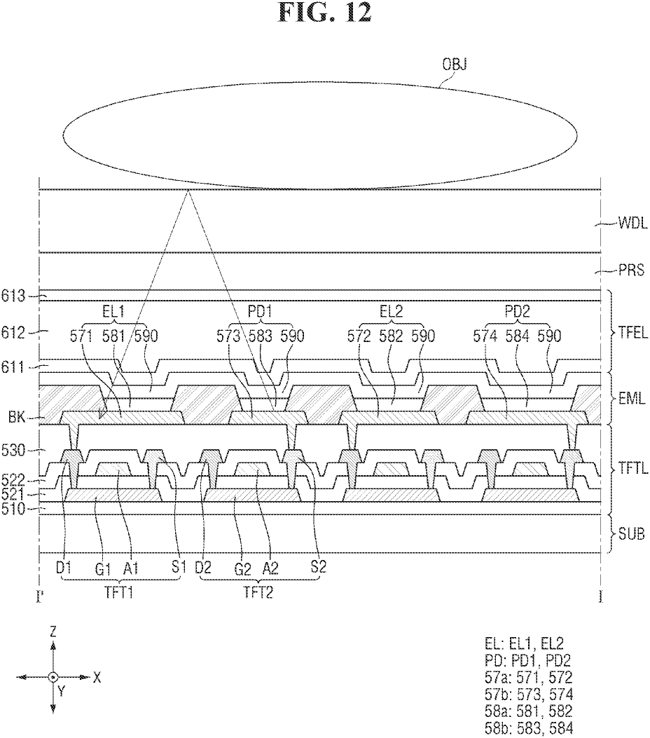

The pressure-sensing circuit 40 may be disposed on the circuit board 30. The pressure-sensing circuit 40 may be implemented as an integrated circuit (IC), and may be attached to the upper surface of the circuit board 30. The pressure-sensing circuit 40 may be connected to the display layer of the display panel 10. The pressure-sensing circuit 40 may sense an electrical signal by pressure applied to a plurality of pressure sensors (e.g., in PRN of FIGS. 4 and 5 and/or in PRS of FIG. 12) of the display panel 10. The pressure-sensing circuit 40 may generate pressure data according to a change in an electrical signal sensed by the pressure sensors, and may transmit the generated pressure data to the main processor 710.

The main circuit board 700 may be either a printed circuit board or a flexible printed circuit board.

The main circuit board 700 may include the main processor 710.

The main processor 710 may control all the functions of the display device 1. For example, the main processor 710 may output digital video data to the display driver 20 through the circuit board 30, so that the display panel 10 displays images. In addition, the main processor 710 may receive touch data from a touch driver circuit to determine coordinates of the user’s touch, and then may execute an application indicated by an icon displayed at the coordinates of the user’s touch.

The main processor 710 may identify a pattern of a fingerprint F (e.g., see FIG. 4) of a finger based on an electrical signal (e.g., a photocurrent) according to a difference in an amount of light input from the light-sensing circuit 50.

The main processor 710 may produce a pulse wave signal PPG reflecting changes in blood according to a heartbeat, based on an optical signal input from the light-sensing circuit 50. In addition, the main processor 710 may calculate a user’s touch pressure according to an electrical signal input from the pressure-sensing circuit 40. In addition, the main processor 710 may calculate the user’s blood pressure based on the pulse wave signal PPG and the pressure signal.

The main processor 710 may be an application processor, a central processing unit, or a system chip implemented as an integrated circuit.

In addition, a mobile communications module (e.g., a mobile communications device), capable of transmitting/receiving a radio signal to/from at least one of a base station, an external terminal, and/or a server over a mobile communications network, may be further mounted on the main circuit board 700. The wireless signal may include various suitable kinds of data, depending on a voice signal, a video call signal, or a text/multimedia message transmission/reception.

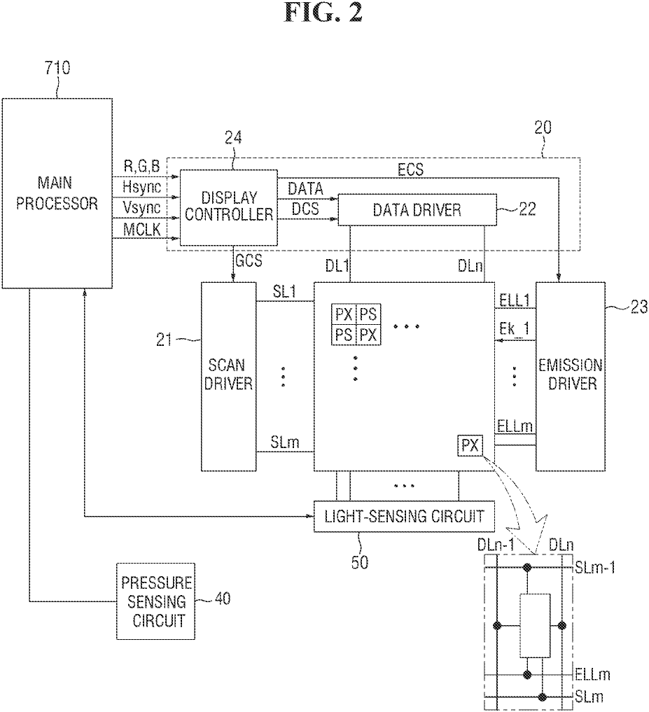

FIG. 2 is a block diagram showing a display device according to an embodiment of the present disclosure.

Referring to FIGS. 1 and 2, the display device 1 includes the display panel 10 including the plurality of pixels PX, the display driver 20, a scan driver 21, an emission driver 23, the light-sensing circuit 50, the pressure-sensing circuit 40, and the main processor 710.

The main processor 710 may receive an optical signal from the light-sensing circuit 50. The main processor 710 may receive a current according to the optical signal to derive ridges RID and valleys VAL of a fingerprint F of a finger (e.g., see FIG. 4). The main processor 710 may identify a pattern of the fingerprint F.

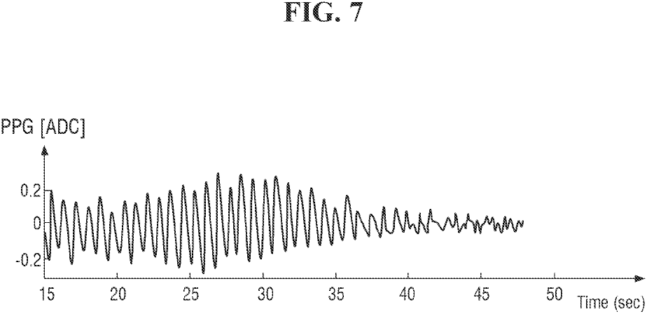

The main processor 710 may receive an optical signal from the light-sensing circuit 50. In addition, the main processor 710 may receive an optical signal from the pressure-sensing circuit 40. The main processor 710 may produce a pulse wave signal PPG reflecting changes in the blood (e.g., see FIG. 7) according to a heartbeat based on the received signals. The main processor 710 may calculate the user’s blood pressure based on the pulse wave signal PPG.

The main processor 710 drives and controls the light-sensing circuit 50, the pressure-sensing circuit 40, and a display controller 24. The main processor 710 may output image information to the display controller 24. For example, the main processor 710 may output image information containing the pulse wave signal PPG, a blood-pressure measurement value, and blood-pressure information to the display controller 24.

The display controller 24 receives an image signal supplied from the main processor 710. In addition, the display controller 24 may generate a scan control signal SCS for controlling an operation timing of the scan driver 21, an emission control signal ECS for controlling an operation timing of the emission driver 23, and a data control signal DCS for controlling an operation timing of the data driver 22. The display controller 24 may output image data DATA and the data control signal DCS to the data driver 22. The display controller 24 may output the scan control signal SCS to the scan driver 21, and may output the emission control signal ECS to the emission driver 23.

The display controller 24 may be electrically connected to the display panel 10 and/or the main processor 710 via lines, or may be connected thereto over a communication network. According to an embodiment of the present disclosure, at least a part of the display controller 24 may be attached directly to the display panel 10 in the form of a driving chip.

The data driver 22 may receive the image data DATA and the data control signal DCS from the display controller 24. The data driver 22 may convert the image data DATA into an analog data voltage according to the data control signal DCS. The data driver 22 may output the converted analog data voltage to a data line from among a plurality of data lines DL1 to DLn, where n is a natural number, in synchronization with a scan signal.

The scan driver 21 may generate scan signals according to the scan control signal SCS, and may sequentially output the scan signals to scan lines SL1 to SLm, where m is a natural number.

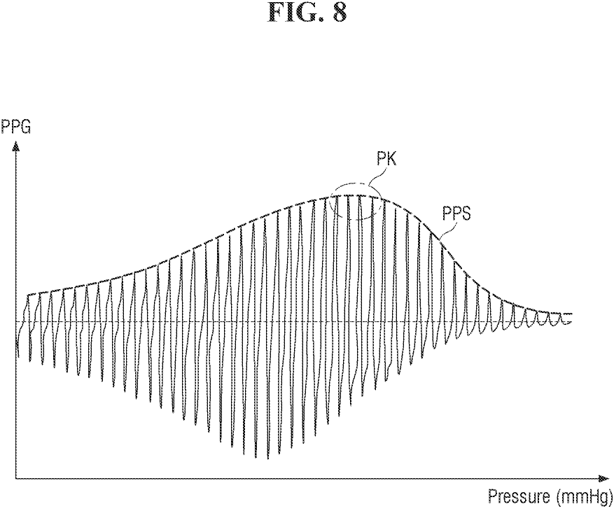

A driving voltage ELVDD (e.g., see FIG. 8), a common voltage ELVSS, and supply voltage lines may be further included. The supply voltage lines may include a driving voltage line and a common voltage line. The driving voltage ELVDD may be a high-level voltage for driving a light-emitting element and a photoelectric conversion element. The common voltage may be a low-level voltage for driving a light-emitting element and a photoelectric conversion element. In other words, the driving voltage may have a higher level than that of the common voltage.

Display control signals may include the scan control signal SCS, the data control signal DCS, and the emission control signal ECS. The display control signals may be output to the scan driver 21, the data driver 22, and the emission driver 23.

The emission driver 23 may generate an emission signal Ek_1 in response to the emission control signal ECS, and may sequentially output the emission signal Ek_1 to emission lines ELL1 to ELLm, where m is a natural number. Although the emission driver 23 is shown in FIG. 2 as being disposed separately from the scan driver 21, the present disclosure is not limited thereto, and the emission driver 23 may be included in the scan driver 21 in some embodiments.

The data driver 22 and the display controller 24 may be included in the display driver 20 described above that controls the operation of the display panel 10. The data driver 22 and the display controller 24 may be implemented as an integrated circuit (IC), and mounted on the display driver 20.

Each of the plurality of pixels PX may be connected to at least one of the scan lines SL1 to SLm, one of the data lines DL1 to DLn, and at least one of the emission lines ELL1 to ELLm.

Each of the plurality of photo sensors PS may be connected to one of the scan lines SL1 to SLm and one of a plurality of read-out lines.

The plurality of scan lines SL1 to SLm may connect the scan driver 21 with the plurality of pixels PX and the plurality of photo sensors PS. The plurality of scan lines SL1 to SLm may provide scan signals output from the scan driver 21 to the plurality of pixels PX.

The plurality of data lines DL1 to DLn may connect the data driver 22 with the plurality of pixels PX. The plurality of data lines DL1 to DLn may provide data signals (e.g., the converted analog data voltage) output from the data driver 22 to the plurality of pixels PX.

The plurality of emission lines ELL1 to ELLm may connect the emission driver 23 with the plurality of pixels PX. The plurality of emission lines ELL1 to ELLm may provide the emission signals Ek_1 output from the emission driver 23 to the plurality of pixels PX.

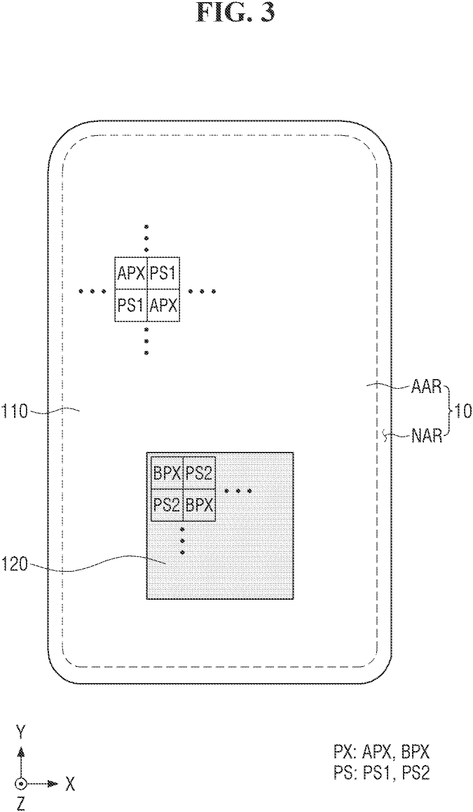

FIG. 3 is a plan view showing areas of a display device according to an embodiment of the present disclosure.

Referring to FIG. 3, the active area AAR includes a fingerprint measurement area 110 and a blood-pressure measurement area 120.

The areas of the active area AAR of the plurality of pixels for measuring a fingerprint may be defined as the fingerprint measurement area 110, and the area for measuring a blood pressure may be defined as the blood-pressure measurement area 120. In more detail, the fingerprint measurement area 110 may emit light. In addition, the fingerprint measurement area 110 may sense an amount or a wavelength of incident light. The fingerprint measurement area 110 may measure a fingerprint by sensing light reflected off a fingerprint of a user OBJ (e.g., see FIG. 4) from the emitted light. In addition, the blood-pressure measurement area 120 may emit light.

The blood-pressure measurement area 120 may sense an amount or wavelength of incident light. The blood-pressure measurement area 120 may measure a blood pressure by sensing light reflected off a fingerprint of the user OBJ from the emitted light. The fingerprint measurement area 110 and the blood-pressure measurement area 120 may overlap with the active area AAR.

For example, the blood-pressure measurement area 120 may be located at (e.g., in or on) a limited area used for blood pressure measurement within the active area AAR. As shown in FIG. 3, the blood-pressure measurement area 120 may be surrounded (e.g., around a periphery thereof) by the fingerprint measurement area 110, and the blood-pressure measurement area 120 may have a rectangular shape when viewed from the top (e.g., in a plan view). In addition, the fingerprint measurement area 110 may be defined as being the same or substantially the same as (e.g., identical to) the active area AAR. In this case, the front surface of the active area AAR may be utilized as an area for fingerprint measurement.

A plurality of fingerprint display pixels APX, and a plurality of fingerprint photo sensors PS1 that are responsive to light may be disposed at (e.g., in or on) the fingerprint measurement area 110. The fingerprint photo sensors PS1 for fingerprint measurement may include photoelectric conversion elements PD (e.g., see FIG. 12) at (e.g., in or on) the fingerprint measurement area 110 to sense incident light, and to convert the incident light into electrical signals.

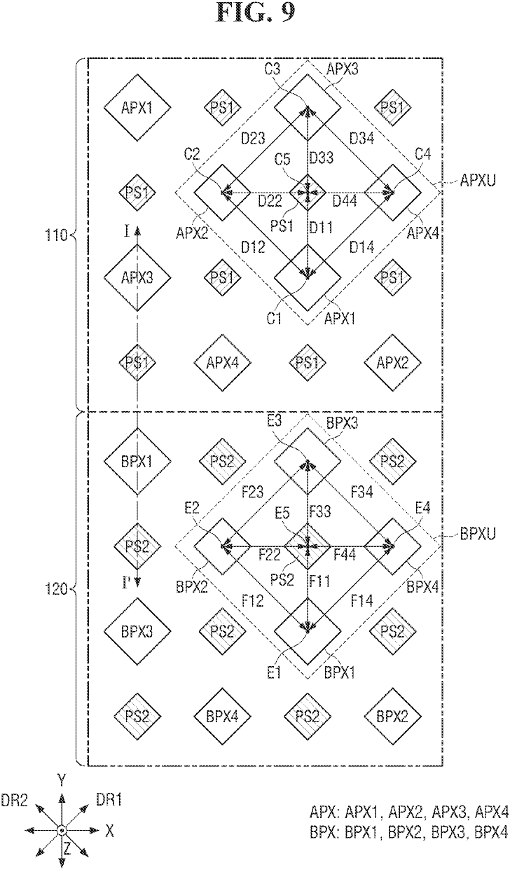

A plurality of blood-pressure display pixels BPX, and a plurality of blood-pressure photo sensors PS2 that are responsive to light may be disposed at (e.g., in or on) the blood-pressure measurement area 120. The blood-pressure photo sensors PS2 for blood-pressure measurement may include photoelectric conversion elements PD (e.g., see FIG. 12) at (e.g., in or on) the blood-pressure measurement area 120 to sense incident light, and to convert the incident light into electrical signals. The fingerprint display pixels APX and the fingerprint photo sensors PS1 at (e.g., in or on) the fingerprint measurement area 110, and the blood-pressure display pixels BPX and the blood-pressure photo sensors PS2 at (e.g., in or on) the blood-pressure measurement area 120 will be described in more detail below with reference to FIG. 9.

FIG. 4 is a cross-sectional view showing a fingerprint detection in a first area according to an embodiment.

Referring to FIG. 4, the fingerprint measurement area 110 may further include a window WDL disposed on the display panel 10. The display panel 10 may include a substrate SUB, a display layer DPL including the fingerprint display pixels APX and the fingerprint photo sensors PS1 disposed on the substrate SUB, and an encapsulation layer TFEL disposed on the display layer DPL. A pressure layer PRN may be disposed on the encapsulation layer TFEL. In another embodiment, the pressure layer PRN may be disposed on the substrate SUB, the display layer DPL including the fingerprint display pixel APX and the fingerprint photo sensors PS1 may be disposed on the pressure layer PRN, and the encapsulation layer TFEL may be disposed on the display layer DPL.

When a finger of the user OBJ comes into contact with the upper surface of the window WDL at (e.g., in or on) the fingerprint measurement area 110, light output from the fingerprint display pixels APX of the display panel 10 may be reflected at ridges RID and valleys VAL between the ridges RID of the user’s fingerprint F. The ridges RID of the fingerprint F may be in contact with the upper surface of the window WDL, and the valleys VAL of the fingerprint F may not be contact with the window WDL. In other words, the upper surface of the window WDL may be in contact with air at the valleys VAL.

When the fingerprint F is in contact with the upper surface of the cover window WDL, light output from the light-emitting unit of a fingerprint display pixel APX may be reflected off the ridges RID and/or the valleys VAL of the fingerprint F. Because the refractive index of the fingerprint F is different from the refractive index of air, the amount of light reflected off the ridges RID of the fingerprint F may be different from the amount of light reflected from the valleys VAL. Accordingly, the ridges RID and the valleys VAL of the fingerprint F may be distinguishably derived based on a difference in the amounts of light incident on the fingerprint photo sensors PS1. Because the fingerprint photo sensors PS1 output an electrical signal (e.g., a photocurrent) based on the difference in the amounts of the light, the pattern of the fingerprint F of the finger may be identified in the fingerprint measurement area 110 of the display panel 10.

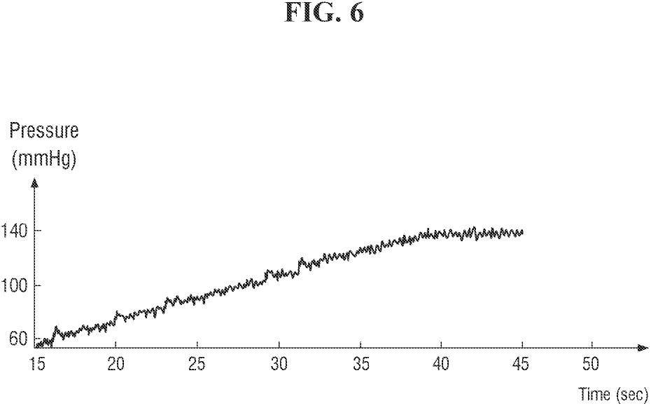

FIG. 5 is a cross-sectional view showing blood-pressure measurement in a second area according to an embodiment. FIG. 6 is a graph showing pressure measurement values verse pressing time. FIG. 7 is a graph showing a pulse wave signal versus pressing time. FIG. 8 is a graph showing a pulse wave signal versus pressure.

Referring to FIG. 5, the blood-pressure measurement area 120 may further include the window WDL disposed on the display panel 10. The display panel 10 may include a substrate SUB, a display layer DPL including the blood-pressure display pixels BPX and the blood-pressure photo sensors PS2 disposed on the substrate SUB, and an encapsulation layer TFEL disposed on display layer DPL. The pressure layer PRN may be disposed between the window WDL and the display panel 10 (e.g., on the encapsulation layer TFEL). In another embodiment, the pressure layer PRN may be disposed on the substrate SUB, the display layer DPL including the blood-pressure display pixels BPX and the blood-pressure photo sensors PS2 may be disposed on the pressure layer PRN, and the encapsulation layer TFEL may be disposed on the display layer DPL.

Referring to FIG. 6, when a finger of a user OBJ comes into contact with the upper surface of the window WDL at (e.g., in or on) the blood-pressure measurement area 120, the pressure layer PRN may measure the pressure applied by the user OBJ. Accordingly, the main processor 710 may calculate pressure data over time. For example, while the user OBJ brings her/his finger into contact with the blood-pressure measurement area 120, the pressure sensed by the pressure layer PRN may gradually increase over time to reach a maximum value. As the contact pressure increases, the blood vessels may constrict, resulting in smaller or zero blood flow rate.

Referring further to FIG. 7, in order to generate a pulse wave signal PPG, pulse wave information over time is also determined along with the pressure data. During a systole of a heart, the blood ejected from the left ventricle of the heart moves to the peripheral tissues, and accordingly, the blood volume in the artery increases. In addition, red blood cells carry more oxygen in hemoglobin to the peripheral tissues during the systole of the heart. During a diastole of the heart, a part of the blood is sucked from the peripheral tissues towards the heart. At this time, when the light emitted from the display pixels is irradiated to the peripheral blood vessels, the irradiated light may be absorbed by the peripheral tissues. The light absorbance is dependent on the hematocrit ratio and the blood volume. The light absorbance may have the maximum value in the systole of the heart, and a minimum value in the diastole of the heart. The light absorbance is in inverse proportion to the amount of light incident on the blood-pressure photo sensors PS2 of the blood-pressure measurement area 120. Therefore, the light absorbance at a suitable time point (e.g., a predetermined or particular time point) may be estimated based on data on the amount of received light incident on the blood-pressure photo sensors PS2. For example, as shown in FIG. 7, values of the pulse wave signal PPG over time may be generated. The blood-pressure photo sensors PS2 are used to receive the light reflected from the user’s peripheral blood vessels, and to recognize a difference in light based on the difference in blood flow in the peripheral blood vessels. Therefore, the blood-pressure photo sensors PS2 is used to sense a larger amount of light than those of the fingerprint photo sensors PS1 that detect a user’s fingerprint.

Referring further to FIG. 8, the main processor 710 may generate the pulse wave signal PPG based on the pressure data and the values of the pulse wave signal PPG. Because the pulse wave signal PPG oscillates according to a heartbeat cycle, the pulse wave signal PPG may reflect a change in the blood pressure according to the heartbeat. The main processor 710 may calculate the blood pressure of the user OBJ in the blood-pressure measurement area 120 using peaks PK of the pulse wave signal PPG.

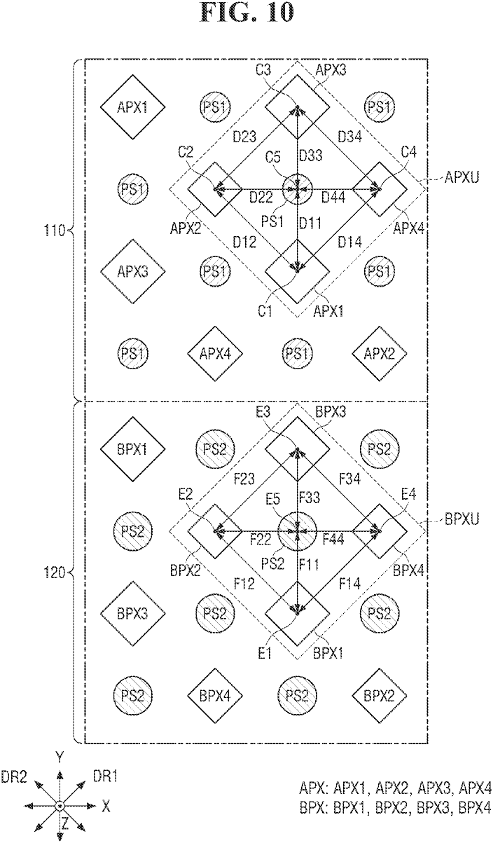

FIG. 9 is a plan view showing a layout of pixels and photo sensors of a display panel according to an embodiment. FIG. 10 is a plan view showing a layout of pixels and photo sensors of a display panel according to another embodiment of the present disclosure.

Referring to FIGS. 9 and 10, a plurality of fingerprint display pixels APX and a plurality of fingerprint photo sensors PS1 may be arranged repeatedly at (e.g., in or on) the fingerprint measurement area 110.

The plurality of fingerprint display pixels APX may include first subsidiary fingerprint pixels APX1, second subsidiary fingerprint pixels APX2, third subsidiary fingerprint pixels APX3, and fourth subsidiary fingerprint pixels APX4. For example, the first subsidiary fingerprint pixels APX1 may emit light of a red wavelength, the second subsidiary fingerprint pixels APX2 and the fourth subsidiary fingerprint pixels APX4 may emit light of a green wavelength, and the third subsidiary fingerprint pixels APX3 may emit light of a blue wavelength. The plurality of fingerprint display pixels APX may include a plurality of emission areas for emitting light. The plurality of fingerprint photo sensors PS1 may include a plurality of light-sensing areas for detecting incident light.

The first subsidiary fingerprint pixels APX1, the second subsidiary fingerprint pixels APX2, the third subsidiary fingerprint pixels APX3, the fourth subsidiary fingerprint pixels APX4, and the plurality of fingerprint photo sensors PS1 may be arranged in a first direction X and a second direction Y crossing (e.g., intersecting) the first direction X. According to an embodiment of the present disclosure, the first subsidiary fingerprint pixels APX1 and the third subsidiary fingerprint pixels APX3 may be arranged alternately with each other in the first direction X to form a first row, and the second subsidiary fingerprint pixels APX2 and the fourth subsidiary fingerprint pixels APX4 may be arranged repeatedly in the first direction X to form a second row adjacent to the first row. The pixels PX belonging to the first row may be arranged in a staggered manner in the first direction X with respect to the pixels PX belonging to the second row. The first row and the second row may be repeatedly arranged up to an mth row, where m is a natural number.

In other words, the first subsidiary fingerprint pixels APX1 and the fourth subsidiary fingerprint pixels APX4 may be arranged in a first diagonal direction DR1 crossing the first direction X and the second direction Y, and the second subsidiary fingerprint pixels APX2 and the third subsidiary fingerprint pixels APX3 may be arranged in the first diagonal direction DR1. The second subsidiary fingerprint pixels APX2 and the first subsidiary fingerprint pixels APX1 may be arranged in a second diagonal direction DR2 crossing the first diagonal direction DR1, and the third subsidiary fingerprint pixels APX3 and the fourth subsidiary fingerprint pixels APX4 may be arranged in the second diagonal direction DR2. The first diagonal direction DR1 may be inclined between the first direction X and the second direction Y, and the second diagonal direction DR2 may be perpendicular to or substantially perpendicular to the first diagonal direction DR1. For example, the first diagonal direction DR1 may be inclined by 45° from the first direction X and the second direction Y, but the present disclosure is not limited thereto.

The fingerprint photo sensors PS1 may be disposed between the first subsidiary fingerprint pixels APX1 and the third subsidiary fingerprint pixels APX3 forming the first row, such that they are spaced apart from one another. The first subsidiary fingerprint pixels APX1, the fingerprint photo sensors PS1, and the third subsidiary fingerprint pixels APX3 may be arranged one after another in the first direction X. The fingerprint photo sensors PS1 may be disposed between the second subsidiary fingerprint pixels APX2 and the fourth subsidiary fingerprint pixels APX4 forming the second row, such that they are spaced apart from one another. The second subsidiary fingerprint pixels APX2, the fingerprint photo sensors PS1, and the fourth subsidiary fingerprint pixels APX4 may be arranged one after another in the first direction X. The number of fingerprint photo sensors PS1 in the first row may be equal to or substantially equal to the number of fingerprint photo sensors PS1 in the second row. The first row and the second row may be repeatedly arranged up to the mth row.

Due to the arrangement positions and planar shapes of the first subsidiary fingerprint pixel APX1, the second subsidiary fingerprint pixel APX2, the third subsidiary fingerprint pixel APX3, and the fourth subsidiary fingerprint pixel APX4, a distance D12 between the center C1 of the first subsidiary fingerprint pixel APX1 and the center C2 of the second subsidiary fingerprint pixel APX2, a distance D23 between the center C2 of the second subsidiary fingerprint pixel APX2 and the center C3 of the third subsidiary fingerprint pixel APX3, a distance D14 between the center C1 of the first subsidiary fingerprint pixel APX1 and the center C4 of the fourth subsidiary fingerprint pixel APX4, and a distance D34 between the center C3 of the third subsidiary fingerprint pixel APX3 and the center C4 of the fourth subsidiary fingerprint pixel APX4 may be the same or substantially the same as each other (e.g., may be all equal or substantially equal to each other).

In addition, due to the arrangement positions and planar shapes of the first subsidiary fingerprint pixel APX1, the second subsidiary fingerprint pixel APX2, the third subsidiary fingerprint pixel APX3, the fourth subsidiary fingerprint pixel APX4, and the fingerprint photo sensors PS1, a distance D11 between the center C1 of the first subsidiary fingerprint pixel APX1 and the center C5 of the fingerprint photo sensor PS1, a distance D22 between the center C2 of the second subsidiary fingerprint pixel APX2 and the center C5 of the fingerprint photo sensor PS1, a distance D33 between the center C3 of the third subsidiary fingerprint pixel APX3 and the center C5 of the fingerprint photo sensor PS1, and a distance D44 between the center C4 of the fourth subsidiary fingerprint pixel APX4 and the center C5 of the fingerprint photo sensor PS1 may be the same or substantially the same as each other (e.g., may be all equal or substantially equal to each other).

Different fingerprint display pixels APX may have emission areas of different sizes from one another. The sizes of the emission areas of the second subsidiary fingerprint pixels APX2 and the fourth subsidiary fingerprint pixels APX4 may be smaller than the sizes of the emission areas of the first subsidiary fingerprint pixels APX1 and/or the third subsidiary fingerprint pixels APX3. Although the shape of each of the pixels PX is illustrated as a diamond in the example shown in the drawings, the shape of each of the pixels PX is not limited thereto, and may be any suitable shape, such as a rectangle, an octagon, a circle, other suitable polygons, or the like.

One fingerprint display pixel unit APXU may include a first subsidiary fingerprint pixel APX1, a second subsidiary fingerprint pixel APX2, a third subsidiary fingerprint pixel APX3, and a fourth subsidiary fingerprint pixel APX4. The fingerprint display pixel unit APXU refers to a group of color pixels capable of expressing suitable grayscale values.

A plurality of blood-pressure display pixels BPX and a plurality of blood-pressure photo sensors PS2 may be arranged repeatedly at (e.g., in or on) the blood-pressure measurement area 120.

The plurality of blood-pressure display pixels BPX may include first subsidiary blood-pressure pixels BPX1, second subsidiary blood-pressure pixels BPX2, third subsidiary blood-pressure pixels BPX3, and fourth subsidiary blood-pressure pixels BPX4. For example, the first subsidiary blood-pressure pixels BPX1 may emit light of a red wavelength, the second subsidiary blood-pressure pixels BPX2 and the fourth subsidiary blood-pressure pixels BPX4 may emit light of a green wavelength, and the third subsidiary blood-pressure pixels BPX3 may emit light of a blue wavelength. The plurality of blood-pressure display pixels BPX may include a plurality of light-emitting areas for emitting light. The plurality of blood-pressure photo sensors PS2 may include a plurality of light-sensing areas for detecting incident light.

The arrangement of the first subsidiary blood-pressure pixels BPX1, the second subsidiary blood-pressure pixels BPX2, the third subsidiary blood-pressure pixels BPX3, and the fourth subsidiary blood-pressure pixels BPX4 may be the same or substantially the same as (e.g., substantially identical to or similar to) the arrangement of the fingerprint display pixels APX described above, and thus, redundant description thereof may not be repeated.

The blood-pressure photo sensors PS2 may be disposed between the first subsidiary blood-pressure pixels BPX1 and the third subsidiary blood-pressure pixels BPX3 forming the first row of the blood-pressure measurement area 120, such that they are spaced apart from one another. The first subsidiary blood-pressure pixels BPX1, the blood-pressure photo sensors PS2, and the third subsidiary blood-pressure pixels BPX3 may be arranged one after another in the first direction X. The blood-pressure photo sensors PS2 may be disposed between the second subsidiary blood-pressure pixels BPX2 and the fourth subsidiary blood-pressure pixels BPX4 forming the second row of the blood-pressure measurement area 120, such that they are spaced apart from one another. The second subsidiary blood-pressure pixels BPX2, the blood-pressure photo sensors PS2, and the fourth subsidiary blood-pressure pixels BPX4 may be arranged one after another in the first direction X. The number of blood-pressure photo sensors PS2 in the first row may be equal to or substantially equal to the number of blood-pressure photo sensors PS2 in the second row. The first row and the second row may be repeatedly arranged up to the mth row.

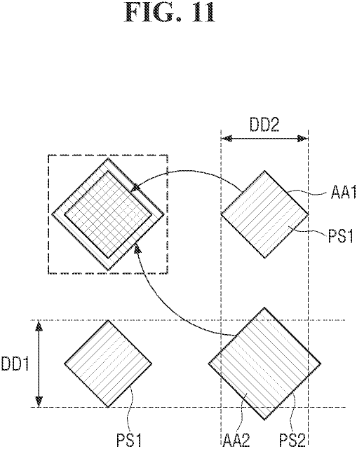

As shown in FIGS. 9 and 10, the area of the blood-pressure photo sensors PS2 may be greater than the area of the fingerprint photo sensors PS1. This will be described in more detail below with reference to FIG. 11.

Due to the arrangement positions and planar shapes of the first subsidiary blood-pressure pixel BPX1, the second subsidiary blood-pressure pixel BPX2, the third subsidiary blood-pressure pixel BPX3, and the fourth subsidiary blood-pressure pixel BPX4, a distance F12 between the center E1 of the first subsidiary blood-pressure pixel BPX1 and the center E2 of the second subsidiary blood-pressure pixel BPX2, a distance F23 between the center E2 of the second subsidiary blood-pressure pixel BPX2 and the center E3 of the third subsidiary blood-pressure pixel BPX3, a distance F14 between the center E1 of the first subsidiary blood-pressure pixel BPX1 and the center E4 of the fourth subsidiary blood-pressure pixel BPX4, and a distance F34 between the center E3 of the third subsidiary blood-pressure pixel BPX3 and the center E4 of the fourth subsidiary blood-pressure pixel BPX4 may be the same or substantially the same as each other (e.g., may be all equal or substantially equal to each other).

In addition, due to the arrangement positions and planar shapes of the first subsidiary blood-pressure pixel BPX1, the second subsidiary blood-pressure pixel BPX2, the third subsidiary blood-pressure pixel NPX3, the fourth subsidiary blood-pressure pixel BPX4, and the blood-pressure photo sensors PS2, a distance F11 between the center E1 of the first subsidiary blood-pressure pixel BPX1 and the center E5 of the blood-pressure photo sensor PS2, a distance F22 between the center E2 of the second subsidiary blood-pressure pixel BPX2 and the center E5 of the blood-pressure sensor PS2, a distance F33 between the center E3 of the third subsidiary blood-pressure pixel BPX3 and the center E5 of the blood-pressure photo sensor PS2, and a distance F44 between the center E4 of the fourth subsidiary blood-pressure pixel BPX4 and the center E5 of the blood-pressure photo sensor PS2 may be the same or substantially the same as each other (e.g., may be all equal or substantially equal to each other).

Different blood-pressure display pixels BPX may have emission areas of different sizes from one another. The sizes of the emission areas of the second subsidiary blood-pressure pixels BPX2 and the fourth subsidiary blood-pressure pixels BPX4 may be smaller than the sizes of the emission areas of the first subsidiary blood-pressure pixels BPX1 and/or the third subsidiary blood-pressure pixels BPX3. Although the shape of each of the pixels PX is illustrated as a diamond in the example shown in the drawings, the shape of each of the pixels PX is not limited thereto, and may have any suitable shape, such as a rectangle, an octagon, a circle, other suitable polygons, or the like.

Although the shapes of the fingerprint photo sensors PS1 and the blood-pressure photo sensors PS2 are illustrated as a diamond in the example shown in FIG. 9, the shape thereof is not limited thereto. As shown in FIG. 10, in another example, the shapes of the fingerprint photo sensors PS1 and the blood-pressure photo sensors PS2 may be a circle. Even in this case, the area of the blood-pressure photo sensors PS2 may be larger than the area of the fingerprint photo sensors PS1. However, the present disclosure is not limited to the examples shown in FIGS. 9 and 10, and the shapes of the fingerprint photo sensors PS1 and the blood-pressure photo sensors PS2 may be any suitable shapes, such as a rectangle, an octagon, other suitable polygonal shapes, or the like.

One blood-pressure display pixel unit BPXU may include a first subsidiary blood-pressure pixel BPX1, a second subsidiary blood-pressure pixel BPX2, a third subsidiary blood-pressure pixel BPX3, and a fourth subsidiary blood-pressure pixel BPX4. The blood-pressure display pixel unit BPXU refers to a group of color pixels capable of expressing suitable grayscale values.

FIG. 11 is a plan view illustrating shapes of photo sensors. In FIG. 11, the dashed-line box at the upper left of the figure shows a shape in which a fingerprint photo sensor PS1 and a blood-pressure photo sensor PS2 are overlapped with each other.

Referring to FIG. 11, an area AA2 of the blood-pressure photo sensors PS2 disposed adjacent to the blood-pressure display pixels BPX may be different from an area AA1 of the fingerprint photo sensors PS1 disposed adjacent to the fingerprint display pixels APX. For example, the area AA2 of the blood-pressure photo sensors PS2 may be greater than the area AA1 of the fingerprint photo sensors PS1 disposed adjacent to the fingerprint display pixels APX. As the area AA2 of the blood-pressure photo sensor PS2 increases, an effective light-receiving area increases, so that a larger amount of light may be received. Accordingly, even though the emissive layers of the blood-pressure photo sensors PS2 and the fingerprint photo sensors PS1 include (e.g., are made of) the same material as each other and have the same or substantially the same thickness as each other, the amount of light received by the blood-pressure photo sensors PS2 may be larger. According to an embodiment of the present disclosure, the amount of light received by the blood-pressure photo sensors PS2 may be equal to or greater than 1.5 times the amount of light received by the fingerprint photo sensors PS1. According to the present embodiment, the area AA2 of the blood-pressure photo sensors PS2 is equal to 1.5 times that of the fingerprint photo sensors PS1, so that the above-described ratio of the amounts of received light may be satisfied.

The shape of the blood-pressure photo sensors PS2 may be the same or substantially the same as (e.g., may be substantially identical to or similar to) that of the fingerprint photo sensors PS1 when viewed from the top (e.g., in a plan view), and may have similar figures as those of the fingerprint photo sensors PS1. Both a first length DD1 and a second length DD2 of the blood-pressure photo sensors PS2 may be greater than those of the fingerprint photo sensors PS1, and a deviation rate of the first length DD1 may be equal to or substantially equal to a deviation rate of the second length DD2. It should be understood, however, that the present disclosure is not limited thereto. For example, in some embodiments, the blood-pressure photo sensors PS2 may have a greater area than those of the fingerprint photo sensors PS1, and may have a different shape from those of the fingerprint photo sensors PS1 when viewed from the top (e.g., in a plan view).

FIG. 12 is a cross-sectional view of pixels and photo sensors according to an embodiment.

Referring to FIG. 12, a buffer layer 510 is disposed on a substrate SUB. The buffer layer 510 may include silicon nitride, silicon oxide, silicon oxynitride, or the like.

A plurality of thin-film transistors including a first thin-film transistor TFT1 and a second thin-film transistor TFT2 may be disposed on the buffer layer 510.

The plurality of thin-film transistors TFT1 and TFT2 may include semiconductor layers A1 and A2, respectively, a gate insulating layer 521 disposed on a part of the semiconductor layers A1 and A2, gate electrodes G1 and G2 on the gate insulating layer 521, an interlayer dielectric film 522 covering the semiconductor layers A1 and A2 and the gate electrodes G1 and G2, and source electrodes S1 and S2 and drain electrodes D1 and D2 on the interlayer dielectric film 522.

The semiconductor layers A1 and A2 may form channels of the first thin-film transistor TFT1 and the second thin-film transistor TFT2, respectively. The semiconductor layers A1 and A2 may include polycrystalline silicon. According to another embodiment, the semiconductor layers A1 and A2 may include monocrystalline silicon, low-temperature polycrystalline silicon, amorphous silicon, or an oxide semiconductor. The oxide semiconductor may include, for example, a binary compound (ABx), a ternary compound (ABxCy), and/or a quaternary compound (ABxCyDz) containing indium, zinc, gallium, tin, titanium, aluminum, hafnium (Hf), zirconium (Zr), magnesium (Mg), and/or the like. Each of the semiconductor layers A1 and A2 may include a channel region, and a source region and a drain region doped with impurities.

The gate insulating layer 521 is disposed on the semiconductor layers A1 and A2. The gate insulating layer 521 electrically insulates the first gate electrode G1 from the first semiconductor layer A1, and electrically insulates the second gate electrode G2 from the second semiconductor layer A2. The gate insulating layer 521 may include (e.g., may be made of) an insulating material, for example, such as silicon oxide (SiOx), silicon nitride (SiNx), a metal oxide, and/or the like.

The first gate electrode G1 of the first thin-film transistor TFT1 and the second gate electrode G2 of the second thin-film transistor TFT2 are disposed on the gate insulating layer 521. The gate electrodes G1 and G2 may be formed above the channel regions of the semiconductor layers A1 and A2, respectively, such that they overlap with the channel regions thereof on the gate insulating layer 521.

The interlayer dielectric film 522 may be disposed on the gate electrodes G1 and G2. The interlayer dielectric film 522 may include one or more inorganic insulating materials, such as silicon oxide (SiOx), silicon nitride (SiNx), silicon oxynitride, hafnium oxide, and/or aluminum oxide. In some embodiments, the interlayer dielectric film 522 may include a plurality of insulating films, and may further include a conductive layer forming a second electrode of a capacitor between the insulating films.

The source electrodes S1 and S2 and the drain electrodes D1 and D2 are disposed on the interlayer dielectric film 522. The first source electrode S1 of the first thin-film transistor TFT1 may be electrically connected to a region (e.g., the drain region or the source region) of the first semiconductor layer A1 through a contact hole penetrating the interlayer dielectric film 522 and the gate insulating layer 521. The second source electrode S2 of the second thin-film transistor TFT2 may be electrically connected to a region (e.g., the drain region or the source region) of the second semiconductor layer A2 through a contact hole penetrating the interlayer dielectric film 522 and the gate insulating layer 521. The source electrodes S1 and S2 and the drain electrodes D1 and D2 may include at least one metal selected from the group consisting of aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

A planarization layer 530 may be formed on the interlayer dielectric film 522 to cover the source electrodes S1 and S2 and the drain electrodes D1 and D2. The planarization layer 530 may include (e.g., may be made of) an organic insulating material and/or the like. The planarization layer 530 may have a flat or substantially flat surface (e.g., upper surface), and may include contact holes exposing the source electrodes S1 and S2 and/or the drain electrodes D1 and D2.

An emission material layer EML may be disposed on the planarization layer 530. The emission material layer EML may include a first light-emitting element EL1, a second light-emitting element EL2, a first photoelectric conversion element PD1, a second photoelectric conversion element PD2, and a bank layer BK. The first light-emitting element EL1 may include a first pixel electrode 571, a first emissive layer 581, and a common electrode 590. The second light-emitting element EL2 may include a second pixel electrode 572, a second emissive layer 582, and the common electrode 590. In addition, the first photoelectric conversion element PD1 may include a first light-receiving electrode 573, a first photoelectric conversion layer 583, and the common electrode 590. The second photoelectric conversion element PD2 may include a second light-receiving electrode 574, a second photoelectric conversion layer 584, and the common electrode 590.

The pixel electrodes 57a of the first light-emitting element EL1 and the second light-emitting element EL2 may be disposed on the planarization layer 530. In more detail, the pixel electrodes 57a may include the first pixel electrode 571 of the first light-emitting element EL1 and the second pixel electrode 572 of the second light-emitting element EL2. In addition, the pixel electrodes 57a may be disposed in the pixels, respectively. The pixel electrodes 57a may be connected to the first source electrode S1 or the first drain electrode D1 of the corresponding first thin-film transistors TFT1 through contact holes penetrating through the planarization layer 530.

The pixel electrode 57a of the light-emitting element EL may have, but is not limited to, a single-layer structure of molybdenum (Mo), titanium (Ti), copper (Cu), or aluminum (Al), or may have a stack of multiple films, such as a multi-layered structure of ITO/Mg, ITO/MgF, ITO/Ag, and/or ITO/Ag/ITO including indium-tin-oxide (ITO), indium-zinc-oxide (IZO), zinc oxide (ZnO), indium oxide (In203), silver (Ag), magnesium (Mg), aluminum (Al), platinum (Pt), lead (Pb), gold (Au), and/or nickel (Ni).

The light-receiving electrodes 57b of the first photoelectric conversion element PD1 and the second photoelectric conversion element PD2 may also be disposed on the planarization layer 530. In more detail, the light-receiving electrode 57b may include the first light-receiving electrode 573 of the first photoelectric conversion element PD1 and the second light-receiving electrode 574 of the second photoelectric conversion element PD2. The light-receiving electrodes 57b may be disposed in the photo sensors. Each of the light-receiving electrodes 57b may be connected to the second source electrode S2 or the second drain electrode D2 of the corresponding second thin-film transistor TFT2 through a contact hole penetrating through the planarization layer 530.

The light-receiving electrode 57b of each of the first photoelectric conversion element PD1 and the second photoelectric conversion element PD2 may have, but is not limited to, a single-layer structure of molybdenum (Mo), titanium (Ti), copper (Cu), or aluminum (Al), or a multi-layered structure of ITO/Mg, ITO/MgF, ITO/Ag, and/or ITO/Ag/ITO.

The bank layer BK may be disposed on the pixel electrodes 57a and the light-receiving electrodes 57b. The bank layer BK may include openings formed over the pixel electrodes 57a, to expose the pixel electrodes 57a, respectively. The regions where the exposed pixel electrodes 57a and the first emissive layer 581 and the second emissive layer 582 overlap with one another may be defined as the emission areas from which different colored light are emitted from different pixels PX.

In addition, the bank layer BK may include openings formed over the light-receiving electrodes 57b, to expose the light-receiving electrodes 57b. The openings exposing the light-receiving electrodes 57b may provide spaces in which the photoelectric conversion layers 58b of the photo sensors PS are formed.

The bank layer BK may include an organic insulating material, such as polyacrylate resin, epoxy resin, phenolic resin, polyamide resin, polyimide resin, unsaturated polyesters resin, poly phenylen ether resin, poly phenylene sulfide resin, and/or benzocyclobutene (BCB). As another example, the bank layer BK may include an inorganic material, such as silicon nitride.

The first emissive layer 581 may be disposed on the first pixel electrode 571 of the first light-emitting element EL1 exposed by the opening of the bank layer BK. In addition, the second emissive layer 582 may be disposed on the second pixel electrode 572 of the second light-emitting element EL2. The first emissive layer 581 and the second emissive layer 582 may include a high-molecular material or a low-molecular material, and different pixels PX may emit red, green and blue light, respectively. The light emitted from the first emissive layer 581 and the second emissive layer 582 may contribute to an image display, or may be used as light sources incident on the photo sensors PS. As described above, the width of the first emissive layer 581 may be equal to or substantially equal to the width of the second emissive layer 582. For example, the width of the first emissive layer 581 of the first subsidiary fingerprint pixel APX1 at (e.g., in or on) the fingerprint measurement area 110 may be equal to or substantially equal to the width of the second emissive layer 582 of the first subsidiary blood-pressure pixel BPX1 at (e.g., in or on) the blood-pressure measurement area 120. In other words, in some embodiments, the emissive layers of the subsidiary fingerprint pixels and the subsidiary blood-pressure pixels that emit the same color as each other may have the same or substantially the same width as each other.

When the first emissive layer 581 and the second emissive layer 582 are formed of an organic material, a hole injecting layer HIL and/or a hole transporting layer HTL may be disposed under (e.g., underneath) the first emissive layer 581 and the second emissive layer 582, and an electron injecting layer EIL and/or an electron transporting layer ETL may be disposed over the first emissive layer 581 and the second emissive layer 582. These layers may have a single-layer structure or a multi-layered structure including at least an organic material.

The first photoelectric conversion layer 583 may be disposed on the first light-receiving electrode 573 of the first photoelectric conversion element PD1 exposed by the opening of the bank layer BK. A region where the exposed first light-receiving electrode 573 and the first photoelectric conversion layer 583 overlap with each other may be defined as a light-sensing area of a corresponding fingerprint photo sensor PS1. The first photoelectric conversion layer 583 may generate photocharges in proportion to the incident light. The incident light may be light that has been emitted from the first emissive layer 581, and then reflected and entered, or may be light provided from the outside irrespective of the light emitted by the first emissive layer 581. Charges generated and accumulated in the first photoelectric conversion layer 583 may be converted into electrical signals used for sensing.

In addition, the second photoelectric conversion layer 584 may be disposed on the second light-receiving electrode 574 of the second photoelectric conversion element PD2 exposed by the opening of the bank layer BK. A region where the exposed second light-receiving electrode 574 and the second photoelectric conversion layer 584 overlap with each other may be defined as a light-sensing area of a corresponding blood-pressure photo sensor PS2. The second photoelectric conversion layer 584 may generate photocharges in proportion to the incident light. The incident light may be light that has been emitted from the second emissive layer 582, and then reflected and entered, or may be light provided from the outside irrespective of the light emitted by the second emissive layer 582. Charges generated and accumulated in the second photoelectric conversion layer 584 may be converted into electrical signals used for sensing.

The width of the second photoelectric conversion layer 584 may be greater than the width of the first photoelectric conversion layer 583. As described above, because the blood-pressure photo sensors PS2 may receive more light than that of the fingerprint photo sensors PS1, the area of the second photoelectric conversion layer 584 may be larger than the area of the first photoelectric conversion layer 583. Accordingly, the width of the second photoelectric conversion layer 584 may be equal to or greater than 1.5 times the width of the first photoelectric conversion layer 583.

The first photoelectric conversion layer 583 and the second photoelectric conversion layer 584 may include an electron-donating material (e.g., electron donors) and an electron-accepting material (e.g., electron acceptors). The electron donors may generate donor ions in response to light, and the electron acceptors may generate acceptor ions in response to light. When the first photoelectric conversion layer 583 and the second photoelectric conversion layer 584 are formed of an organic material, the electron donors may include, but is not limited to, a suitable compound, such as subphthalocyanine (SubPc) and/or dibutylphosphate (DBP). The electron acceptors may include, but is not limited to, a suitable compound, such as fullerene, a fullerene derivative, and/or perylene diimide.

As another example, when the first photoelectric conversion layer 583 and the second photoelectric conversion layer 584 are formed of an inorganic material, the first photoelectric conversion element PD1 and the second photoelectric conversion element PD2 may be a p-n junction or a pin-type phototransistor. For example, the first photoelectric conversion layer 583 and the second photoelectric conversion layer 584 may have a structure in which an n-type semiconductor layer, an i-type semiconductor layer, and a p-type semiconductor layer are sequentially stacked on one another.

When the first photoelectric conversion layer 583 and the second photoelectric conversion layer 584 are formed of an organic material, a hole injecting layer HIL and/or a hole transporting layer HTL may be disposed under (e.g., underneath) the first photoelectric conversion layer 583 and the second photoelectric conversion layer 584, and an electron injecting layer EIL and/or an electron transporting layer ETL may be disposed over the first photoelectric conversion layer 583 and the second photoelectric conversion layer 584. These layers may have a single-layer structure or a multi-layered structure including at least an organic material.

The common electrode 590 may be disposed on the first emissive layer 581, the second emissive layer 582, the first photoelectric conversion layer 583, the second photoelectric conversion layer 584, and the bank layer BK. The common electrode 590 may be disposed throughout the pixels PX and the photo sensors PS, such that the common electrode 590 covers the first emissive layer 581, the second emissive layer 582, the first photoelectric conversion layer 583, the second photoelectric conversion layer 584, and the bank layer BK. The common electrode 590 may include a conductive material having a low work function, for example, such as Li, Ca, LiF/Ca, LiF/Al, Al, Mg, Ag, Pt, Pd, Ni, Au, Nd, Ir, Cr, BaF, Ba, or a suitable compound or mixture thereof (e.g., a mixture of Ag and Mg). As another example, the common electrode CE may include a transparent metal oxide, for example, such as indium-tin-oxide (ITO), indium-zinc-oxide (IZO), zinc oxide (ZnO), and/or the like.

The common electrode 590 may be commonly disposed on the first emissive layer 581, the second emissive layer 582, the first photoelectric conversion layer 583, and the second photoelectric conversion layer 584. In this case, in some embodiments, the cathode electrodes of the first light-emitting element EL1 and the second light-emitting element EL2 may be electrically connected to the sensing cathode electrodes of the first photoelectric conversion element PD1 and the second photoelectric conversion element PD2. For example, the common voltage line connected to the cathode electrodes of the first light-emitting element EL1 and the second light-emitting element EL2 may be electrically connected to the sensing cathode electrodes of the first photoelectric conversion element PD1 and the second photoelectric conversion element PD2.

The encapsulation layer TFEL may be disposed on the emission material layer EML. The encapsulation layer TFEL may include at least one inorganic film to prevent or substantially prevent oxygen and/or moisture from penetrating into each of the first emissive layer 581, the second emissive layer 582, the first photoelectric conversion layer 583, and the second photoelectric conversion layer 584. In addition, the encapsulation layer TFEL may include at least one organic film to protect each of the first emissive layer 581, the second emissive layer 582, the first photoelectric conversion layer 583, and the second photoelectric conversion layer 584 from particles, such as dust. For example, the encapsulation layer TFEL may have a stacked structure of a first inorganic film 611, an organic film 612, and a second inorganic film 613. The first inorganic film 611 and the second inorganic film 613 may include (e.g., may be made up of) multiple films, in which one or more inorganic films of a silicon nitride layer, a silicon oxynitride layer, a silicon oxide layer, a titanium oxide layer, and/or an aluminum oxide layer are alternately stacked on one another. The organic film 612 may be an acryl resin, an epoxy resin, a phenolic resin, a polyamide resin, or a polyimide resin.

A pressure-sensing layer PRS (which may correspond to the pressure layer PRN described above with reference to FIGS. 4 and 5) may be disposed on the encapsulation layer TFEL. The pressure-sensing layer PRS may be disposed in the form of a panel or a film, and may be attached on the encapsulation layer TFEL by a bonding layer, such as a pressure-sensitive adhesive (PSA). Because the pressure-sensing layer PRS is positioned on paths of the light emitted from the display layer, it may be transparent.

The pressure-sensing layer PRS may sense a pressure applied to the display device 1. When a user OBJ touches the upper surface of the display device 1, a pressing force of the touch input may be sensed by the pressure-sensing layer PRS. Pressure-sensing electrodes of the pressure-sensing layer PRS may be formed directly on the touch layer. In this case, the pressure-sensing layer PRS may be incorporated into the display panel 10, together with the display layer and the touch layer.

The window WDL may be disposed on the pressure-sensing layer PRS. The window WDL may be disposed at a top (e.g., a front) of the display device 1, after display cells undergo a cutting process and a module process, to protect the elements of the display device 1. The window WDL may be made of glass or plastic.

According to the present embodiment, the amount of light received by the photo sensors PS at (e.g., in or on) the fingerprint measurement area 110 for detecting a fingerprint may be different from that of the photo sensors PS at (e.g., in or on) the blood-pressure measurement area 120 for measuring a blood pressure. Accordingly, by disposing two kinds of photo sensors PS having different areas from one another, one at (e.g., in or on) the fingerprint measuring area 110 and the other at (e.g., in or on) the blood pressure measuring area 120, the display device 1 capable of measuring a fingerprint as well as a blood pressure may be provided.

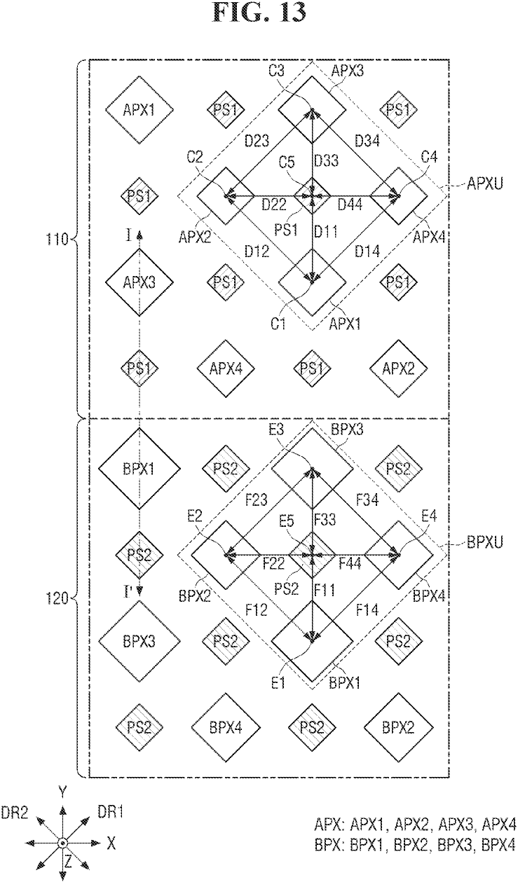

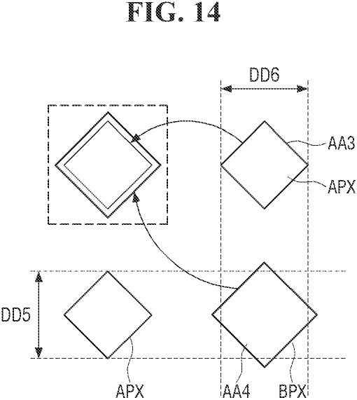

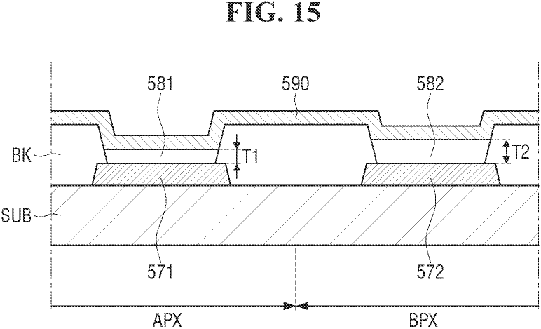

FIG. 13 is a plan view showing a layout of pixels and photo sensors of a display panel according to another embodiment of the present disclosure. FIG. 14 is a plan view illustrating shapes of pixels according to another embodiment. FIG. 15 illustrates cross-sectional views of pixels according to another embodiment.

The embodiments of FIGS. 13 to 15 may be the same or substantially the same as (e.g., substantially identical or similar to) one or more of the embodiments described above with reference to FIGS. 9 to 12, except that the areas of the first to fourth subsidiary blood-pressure pixels BPX1, BPX2, BPX3, and BPX4 of the blood-pressure measurement area 120 may be different. Accordingly, redundant description thereof may not be repeated, and the differences therebetween may be mainly described hereinafter.

Referring to FIG. 13, a plurality of fingerprint display pixels APX and a plurality of fingerprint photo sensors PS1 may be arranged repeatedly at (e.g., in or on) the fingerprint measurement area 110. The plurality of fingerprint display pixels APX may include the first subsidiary fingerprint pixels APX1, the second subsidiary fingerprint pixels APX2, the third subsidiary fingerprint pixels APX3, and the fourth subsidiary fingerprint pixels APX4. In addition, a plurality of blood-pressure display pixels BPX and a plurality of blood-pressure photo sensors PS2 may be arranged repeatedly at (e.g., in or on) the blood-pressure measurement area 120. The plurality of blood-pressure display pixels BPX may include the first subsidiary blood-pressure pixels BPX1, the second subsidiary blood-pressure pixels BPX2, the third subsidiary blood-pressure pixels BPX3, and the fourth subsidiary blood-pressure pixels BPX4. The arrangements of the fingerprint display pixels APX and the blood-pressure display pixels BPX are the same or substantially the same as (e.g., substantially identical or similar to) those described above with reference to FIGS. 9 to 12, and thus, redundant description thereof may not be repeated.

In FIG. 14, a dashed-line box at the upper left shows a shape in which a subsidiary fingerprint pixel APX (e.g., a first subsidiary fingerprint pixel APX1) of the fingerprint measurement area 110 and a subsidiary blood-pressure pixel BPX (e.g., a first subsidiary blood-pressure pixel BPX1) of the blood-pressure measurement area 120 are overlapped with each other. Hereinafter, for convenience, the subsidiary fingerprint pixel APX and the subsidiary blood-pressure pixel BPX may be described in more detail in the context of the first subsidiary fingerprint pixel APX1 and the first subsidiary blood-pressure pixel BPX1.

Referring to FIG. 14, the first subsidiary blood-pressure pixel BPX1 of the blood-pressure measurement area 120 has a larger area than that of the first subsidiary fingerprint pixel APX1 of the fingerprint measurement area 110. As the area of the active area increases, the effective emission area increases, and thus, a maximum luminance may be increased. Accordingly, even though the emissive layers of the first subsidiary blood-pressure pixel BPX1 of the blood-pressure measurement area 120 and the first subsidiary fingerprint pixel APX1 of the fingerprint measurement area 110 include (e.g., are made of) the same material as each other and have the same or substantially the same thickness as each other, the maximum luminance of the first subsidiary blood-pressure pixel BPX1 of the blood-pressure measurement area 120 may be relatively larger. According to an embodiment of the present disclosure, the maximum luminance of the first subsidiary blood-pressure pixel BPX1 of the blood-pressure measurement area 120 may be 1.5 to 3 times the maximum luminance of the first subsidiary fingerprint pixel APX1 of the fingerprint measurement area 110. According to the present embodiment, the area of the first subsidiary blood-pressure pixel BPX1 of the blood-pressure measurement area 120 is equal to or greater than 1.5, and equal to or less than 3 times that of the first subsidiary fingerprint pixel APX1 of the fingerprint measurement area 110, and thus, the above-described ratio of the maximum luminances may be satisfied.

The shape of the first subsidiary blood-pressure pixel BPX1 of the blood-pressure measurement area 120 may be the same or substantially the same as (e.g., substantially identical or similar to) that of the first subsidiary fingerprint pixel APX1 of the fingerprint measurement area 110 when viewed from the top (e.g., in a plan view), and may have a similar figure as that of the subsidiary fingerprint pixel APX1. A fifth length DD5 and the sixth length DD6 of the first subsidiary blood-pressure pixel BPX1 of the blood-pressure measurement area 120 may be greater than those of the first subsidiary fingerprint pixel APX1 of the fingerprint measurement area 110, and a deviation rate of the fifth length DD5 may be equal to or substantially equal to a deviation rate of the sixth length DD6. However, the present disclosure is not limited thereto. The first subsidiary blood-pressure pixel BPX1 of the blood-pressure measurement area 120 may have a larger area than that of the first subsidiary fingerprint pixel APX1 of the fingerprint measurement area 110, and may have a different shape from that of the first subsidiary fingerprint pixel APX1 when viewed from the top (e.g., in a plan view).

In the example shown in FIG. 15, a thickness T2 of the second emissive layer 582 of the first subsidiary blood-pressure pixel BPX1 at (e.g., in or on) the blood-pressure measurement area 120 is greater than a thickness T1 of the first emissive layer 581 of the first subsidiary fingerprint pixel APX1 at (e.g., in or on) the fingerprint measurement area 110. As shown in FIG. 15, as the thickness T2 of the second emissive layer 582 is greater than the thickness T1 of the first emissive layer 581, the emission volume increases, and thus, a greater amount of light emission may be obtained. Accordingly, even though the first subsidiary blood-pressure pixel BPX1 of the blood-pressure measurement area 120 and the first subsidiary fingerprint pixel APX1 of the fingerprint measurement area 110 have the active areas of the same or substantially the same size as each other (e.g., in a plan view), and the emissive layers including (e.g., made of) the same material as each other, the first subsidiary blood-pressure pixel BPX1 of the blood-pressure measurement area 120 may exhibit a greater amount of light emission than that of the first subsidiary fingerprint pixel APX1 of the fingerprint measurement area 110.

In addition, in some embodiments, the emissive layers of the first subsidiary blood-pressure pixel BPX1 and the first subsidiary fingerprint pixel APX1 may have different luminous materials and/or characteristics from each other. For example, the luminous material of the second emissive layer 582 may have a greater luminous efficiency than that of the luminous material of the first emissive layer 581. In more detail, the luminous material has intrinsic luminous efficiency. Some luminous materials have lower luminous efficiency (e.g., the slope of the transition period of the luminance graph is small), while some other luminous materials have higher luminous efficiency. In addition, while some luminous materials have accurate color gamut, other luminous materials may not have an accurate color gamut. For example, assume that a luminous material A has a somewhat low luminous efficiency, but may realize excellent color gamut. A luminous material B has a luminous efficiency twice or more than that of the luminous material A, but has a relatively poorer color gamut. Then, the luminous material A may be applied to the first emissive layer 581 of the fingerprint measurement area 110 to achieve excellent image quality, and the luminous material B may be applied to the second emissive layer 582 of the blood pressure measurement region 120 to have a maximum luminance of 1.5 to 3 times that of the first emissive layer 581.

According to one or more embodiments, because both the first emissive layer 581 and the second emissive layer 582 contribute to light emission, by adjusting the areas, the thicknesses, the luminous materials, and/or the like of the first emissive layer 581 and the second emissive layer 582, it may be possible to increase the maximum luminance of the first subsidiary blood-pressure pixel BPX1 of the blood-pressure measurement area 120 to be larger than the maximum luminance of the first subsidiary fingerprint pixel APX1 of the fingerprint measurement area 110.

According to one or more embodiments, the amount of light received by the photo sensors PS at (e.g., in or on) the fingerprint measurement area 110 for detecting a fingerprint may be different from that of the photo sensors PS at (e.g., in or on) the blood-pressure measurement area 120 for measuring blood pressure. Accordingly, by separately disposing two kinds of the photo sensors PS having different areas, one at (e.g., in or on) the fingerprint measuring area 110 and the other at (e.g., in or on) the blood pressure measuring area 120, it may be possible to provide the display device 1 capable of measuring a fingerprint as well as a blood pressure.

In addition, in order to measure the blood pressure, more light may be used than that used to detect the fingerprint. Accordingly, because the maximum luminance of the blood-pressure display pixels BPX of the blood-pressure measurement area 120 is greater than the maximum luminance of the fingerprint display pixels APX, the blood pressure may be measured more accurately.

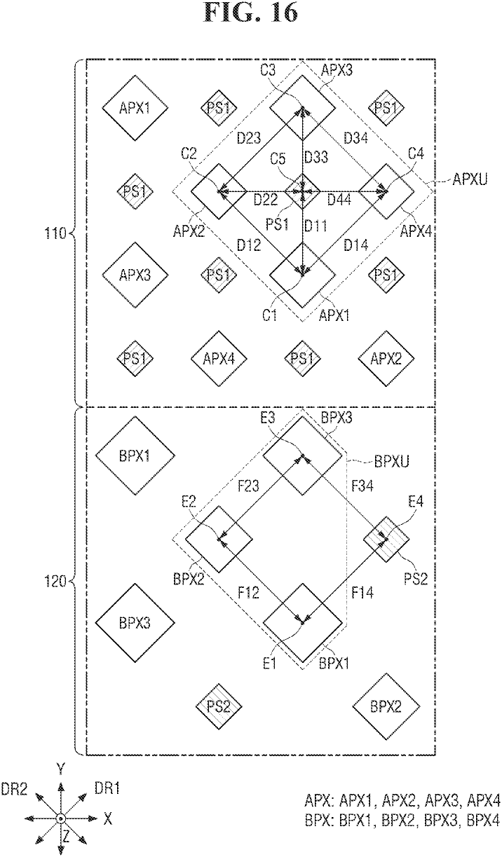

FIG. 16 is a plan view showing a layout of pixels and photo sensors of a display panel according to another embodiment of the present disclosure.

The embodiment shown in FIG. 16 may be the same or substantially the same as (e.g., substantially identical or similar to) one or more of the embodiments described above with reference to FIGS. 13 to 15, except that the fourth subsidiary blood-pressure pixels BPX4 may be omitted, and the arrangement of the first to third subsidiary blood-pressure pixels BPX1, BPX2, and BPX3 and the blood-pressure photo sensors PS2 at (e.g., in or on) the blood-pressure measurement area 120 may be different. Accordingly, redundant description thereof may not be repeated, and the differences therebetween may be mainly described hereinafter.

Referring to FIG. 16, a plurality of blood-pressure display pixels BPX and a plurality of blood-pressure photo sensors PS2 may be arranged repeatedly at (e.g., in or on) the blood-pressure measurement area 120.

The plurality of blood-pressure display pixels BPX may include the first subsidiary blood-pressure pixel BPX1, the second subsidiary blood-pressure pixel BPX2, and the third subsidiary blood-pressure pixel BPX3. For example, the first subsidiary blood-pressure pixel BPX1 may emit light of a red wavelength, the second subsidiary blood-pressure pixel BPX2 may emit light of a green wavelength, and the third subsidiary blood-pressure pixel BPX3 may emit light of a blue wavelength. The plurality of blood-pressure display pixels BPX may include a plurality of light-emitting areas for emitting light. The plurality of blood-pressure photo sensors PS2 may include a plurality of light-sensing areas for detecting incident light.

The first subsidiary blood-pressure pixel BPX1, the second subsidiary blood-pressure pixel BPX2, the third subsidiary blood-pressure pixel BPX3 and the plurality of blood-pressure photo sensors PS2 may be arranged one after another in the first direction X and the second direction Y. According to the present embodiment, the first subsidiary blood-pressure pixels BPX1 and the third subsidiary blood-pressure pixels BPX3 may be arranged alternately in the first direction X to form a first row of the blood-pressure measurement area 120, and the second subsidiary blood-pressure pixels BPX2 and the blood-pressure photo sensors PS2 may be arranged repeatedly in the first direction X to form a second row of the blood-pressure measurement area 120 adjacent to the first row. The pixels PX belonging to the first row may be arranged in a staggered manner in the first direction X with respect to the pixels PX belonging to the second row. The first row and the second row may be repeatedly arranged up to the mth row.

In other words, the first subsidiary blood-pressure pixels BPX1 and the blood-pressure photo sensors PS2 may be arranged in the first diagonal direction DR1 crossing the first direction X and the second direction Y, and the second subsidiary blood-pressure pixels BPX2 and the third subsidiary blood-pressure pixels BPX3 may be arranged in the first diagonal direction DR1. The second subsidiary blood-pressure pixels BPX2 and the first subsidiary blood-pressure pixels BPX1 may be arranged in a second diagonal direction DR2 crossing the first diagonal direction DR1, and the third subsidiary blood-pressure pixels BPX3 and the blood-pressure photo sensor PS2 may be arranged in the second diagonal direction DR2. The first diagonal direction DR1 may be inclined between the first direction X and the second direction Y, and the second diagonal direction DR2 may be perpendicular to or substantially perpendicular to the first diagonal direction DR1. For example, the first diagonal direction DR1 may be inclined by 45° from the first direction X and the second direction Y, but the present disclosure is not limited thereto.

As described above, the area of the blood-pressure photo sensors PS2 may be larger than the area of the fingerprint photo sensors PS1. Accordingly, redundant description thereof may not be repeated.

Due to the arrangement positions and planar shapes of the first subsidiary blood-pressure pixel BPX1, the second subsidiary blood-pressure pixel BPX2, the third subsidiary blood-pressure pixel BPX3, and the blood-pressure photo sensors PS2, a distance F12 between the center E1 of the first subsidiary blood-pressure pixel BPX1 and the center E2 of the second subsidiary blood-pressure pixel BPX2, a distance F23 between the center E2 of the second subsidiary blood-pressure pixel BPX2 and the center E3 of the third subsidiary blood-pressure pixel BPX3, a distance F14 between the center E1 of the first subsidiary blood-pressure pixel BPX1 and the center E4 of the blood-pressure photo sensor PS2, and a distance F34 between the center E3 of the third subsidiary blood-pressure pixel BPX3 and the center E4 of the blood-pressure photo sensor PS2 may be all equal or substantially equal to each other.

Different blood-pressure display pixels BPX may have emission areas of different sizes from one another. The sizes of the emission areas of the second subsidiary blood-pressure pixels BPX2 may be smaller than the sizes of the emission areas of the first subsidiary blood-pressure pixels BPX1 and/or the third subsidiary blood-pressure pixels BPX3. Although the shape of each of the pixels PX is illustrated as a diamond in the example shown in FIG. 16, the shape of each of the pixels PX is not limited thereto, and may have any suitable shape, such as a rectangle, an octagon, a circle, or other suitable polygons.

Although the shapes of the fingerprint photo sensors PS1 and the blood-pressure photo sensors PS2 is illustrated as a diamond in the example shown in FIG. 16, the shapes are not limited thereto, as described above. The shapes of the fingerprint photo sensors PS1 and the blood-pressure photo sensors PS2 may be any suitable shape, such as a rectangle, an octagon, or other suitable polygonal shapes.

One blood-pressure display pixel unit BPXU may include a first subsidiary blood-pressure pixel BPX1, a second subsidiary blood-pressure pixel BPX2, and a third subsidiary blood-pressure pixel BPX3. The blood-pressure display pixel unit BPXU refers to a group of color pixels capable of expressing suitable grayscale values.

Also, in the present embodiment, the amount of light received by the photo sensors PS at (e.g., in or on) the fingerprint measurement area 110 for detecting a fingerprint is different from that by the photo sensors PS at (e.g., in or on) the blood-pressure measurement area 120 for measuring a blood pressure. Accordingly, by disposing the photo sensors PS having different areas from one another at (e.g., in or on) the fingerprint measuring area 110 and the blood pressure measuring area 120, it may be possible to provide the display device 1 capable of measuring a fingerprint as well as a blood pressure.

In addition, as the blood-pressure photo sensor PS2 in FIG. 16 is disposed at the position of the fourth subsidiary blood-pressure pixel BPX4 (e.g., see FIGS. 9 and 10) at (e.g., in or on) the blood-pressure measurement area 120, a larger blood-pressure photo sensor PS2 may be disposed. In other words, by disposing the blood-pressure photo sensor PS2 having a larger area, the accuracy of blood-pressure measurement may be improved.

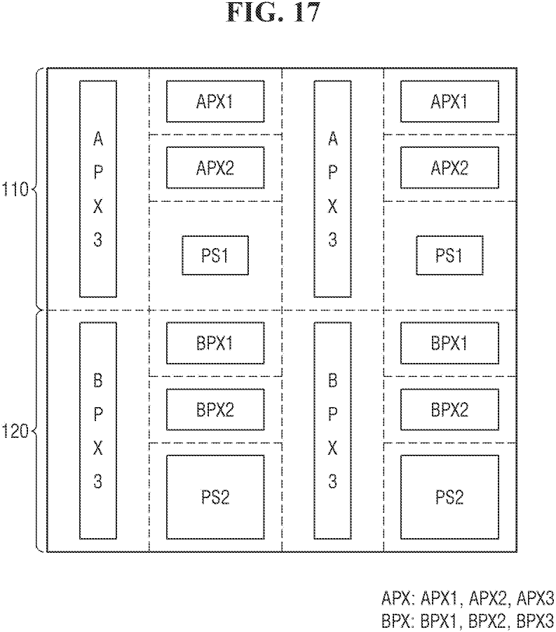

FIG. 17 is a plan view showing a layout of pixels and photo sensors of a display panel according to another embodiment of the present disclosure.

The display device 1 according to the embodiment shown in FIG. 17 may be different from the display device according to one or more of the above-described embodiments, in that the fourth subsidiary fingerprint pixels APX4 and the fourth subsidiary blood-pressure pixels BPX4 may be omitted, and the arrangement relationships of the first to third subsidiary fingerprint pixels APX1, APX2, and APX3 at (e.g., in or on) the fingerprint measurement area 110 and the first to third subsidiary blood-pressure pixels BPX1, BPX2, and BPX3 at (e.g., in or on) the blood-pressure measurement area 120 may be different. Accordingly, redundant description thereof may not be repeated, and the differences therebetween may be mainly described hereinafter.

According to an embodiment of the present disclosure, the first subsidiary fingerprint pixels APX1, the second subsidiary fingerprint pixels APX2, the third subsidiary fingerprint pixels APX3, and the fingerprint photo sensors PS1 may be arranged one after another at (e.g., in or on) the fingerprint measurement area 110 to form a matrix. The third subsidiary fingerprint pixels APX3 may be arranged in the second direction Y to form a first column at (e.g., in or on) the fingerprint measurement area 110, such that the third subsidiary fingerprint pixels APX3 are spaced apart from one another. The first subsidiary fingerprint pixels APX1 and the second subsidiary fingerprint pixel APX2 may be arranged alternately in the second direction Y to form a second column adjacent to the first column at (e.g., in or on) the fingerprint measurement area 110. The arrangement of the sub-pixels may be repeated up to an nth column, where n is a natural number. A combination of the first subsidiary fingerprint pixel APX1, the second subsidiary fingerprint pixel APX2 and the third subsidiary fingerprint pixel APX3 arranged at (e.g., in or on) the fingerprint measurement area 110 may form a single unit pixel.

When the fingerprint photo sensors PS1 are disposed at (e.g., in or on) the fingerprint measurement area 110, the third subsidiary fingerprint pixels APX3 of the fingerprint measurement area 110 may be arranged in odd-numbered columns in the second direction Y, such that they are spaced apart from one another by a suitable distance (e.g., a predetermined distance), and the first subsidiary fingerprint pixels APX1 of the fingerprint measurement area 110, the second subsidiary fingerprint pixels APX2 of the fingerprint measurement area 110, and the blood-pressure photo sensor PS2 may be alternately arranged in even-numbered columns in the second direction Y. For example, in the second column, the first subsidiary fingerprint pixel APX1 of the fingerprint measurement area 110, the second subsidiary fingerprint pixel APX2 of the fingerprint measurement area 110, and the fingerprint photo sensor PS1 may be arranged in that order in the second direction Y.

In addition, the first subsidiary blood-pressure pixels BPX1, the second subsidiary blood-pressure pixels BPX2, the third subsidiary blood-pressure pixels BPX3, and the blood-pressure photo sensors PS2 of the blood-pressure measurement area 120 may be arranged one after another to form a matrix. The third subsidiary blood-pressure pixels BPX3 may be arranged in the second direction Y to form a first column at (e.g., in or on) the blood-pressure measurement area 120, such that the third subsidiary blood-pressure pixels BPX3 are spaced apart from one another. The first subsidiary blood-pressure pixels BPX1 and the second subsidiary blood-pressure pixels BPX2 may be arranged alternately in the second direction Y to form a second column at (e.g., in or on) the blood-pressure measurement area 120. The arrangement of the sub-pixels may be repeated up to the nth column. A combination of the first subsidiary blood-pressure pixel BPX1, the second subsidiary blood-pressure pixel BPX2, and the third subsidiary blood-pressure pixel BPX3 arranged at (e.g., in or on) the blood-pressure measurement area 120 may form a single unit pixel.

When the blood-pressure photo sensors PS2 are disposed at (e.g., in or on) the blood-pressure measurement area 120, the third subsidiary blood-pressure pixels BPX3 of the blood-pressure measurement area 120 are arranged in odd-numbered columns in the second direction Y, such that they are spaced apart from one another by a suitable distance (e.g., a predetermined distance), and the first subsidiary blood-pressure pixels BPX1 of the blood-pressure measurement area 120, the second subsidiary blood-pressure pixels BPX2 of the blood-pressure measurement area 120, and the blood-pressure photo sensors PS2 may be alternately arranged in even-numbered columns in the second direction Y. For example, in the second column, the first subsidiary blood-pressure pixel BPX1 of the blood-pressure measurement area 120, the second subsidiary blood-pressure pixel BPX2 of the blood-pressure measurement area 120, and the blood-pressure photo sensor PS2 may be arranged in that order in the second direction Y.

Incidentally, in each of the fingerprint measurement area 110 and the blood-pressure measurement area 120, the sub-pixels may have different areas from one another. For example, the third sub-pixels APX3 and BPX3 may be larger than the first sub-pixels APX1 and BPX1 and the second sub-pixels APX2 and BPX2. Although the sub-pixels may have a rectangular or square shape when viewed from the top (e.g., in a plan view), the present disclosure is not limited thereto. For example, each of the sub-pixels may have a circle shape or other suitable polygonal shapes, such as an octagon or a diamond.

Also, in the present embodiment, the area of the blood-pressure photo sensors PS2 may be larger than the area of the fingerprint photo sensors PS1. Accordingly, the amount of light received by the photo sensors PS at (e.g., in or on) the fingerprint measurement area 110 for detecting a fingerprint is different from that of the photo sensors PS at (e.g., in or on) the blood-pressure measurement area 120 for measuring a blood pressure. Accordingly, by disposing the photo sensors PS having different areas from one another at (e.g., in or on) the fingerprint measuring area 110 and the blood pressure measuring area 120, it may be possible to provide the display device 1 capable of measuring a fingerprint as well as a blood pressure.

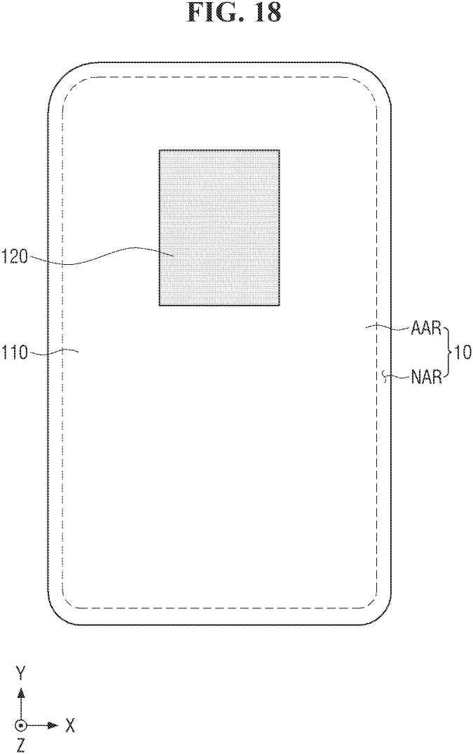

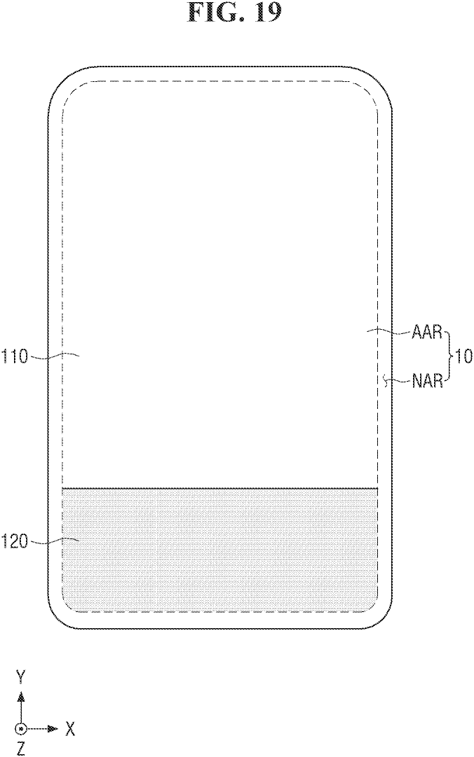

FIGS. 18 and 19 are plan views showing areas of a display device according to one or more embodiments of the present disclosure.

Referring to FIGS. 18 and 19, according to one or more embodiments, the blood-pressure measurement area 120 and the fingerprint measurement area 110 may have various suitable arrangements within the active area AAR. For example, as shown in FIG. 18, the blood-pressure measurement area 120 may be located at an upper end of the active area AAR, while the fingerprint measurement area 110 may surround (e.g., around a periphery of) the blood-pressure measurement area 120. As another example, as shown in FIG. 19, the blood-pressure measurement area 120 may be located at a lower end of the active area AAR, while the fingerprint measurement area 110 may be located at the upper end of the active area AAR. However, the present disclosure is not limited thereto. The arrangement of the blood-pressure measuring area 120 and the fingerprint measuring area 110 may be variously modified at (e.g., in or on) the active area AAR and/or the display area as needed or desired.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a first area comprising a plurality of first pixels;
a second area adjacent to the first area, and comprising a plurality of second pixels;
a first photo sensor adjacent to the plurality of first pixels at the first area, and configured to sense light; and
a second photo sensor adjacent to the plurality of second pixels at the second area, and configured to sense light,
wherein a size of an area of the second photo sensor is different from a size of an area of the first photo sensor.

2. The display device of claim 1, wherein the size of the area of the second photo sensor is larger than the size of the area of the first photo sensor.

3. The display device of claim 2, wherein the size of the area of the second photo sensor is greater than or equal to 1.5 times the size of the area of the first photo sensor.

4. The display device of claim 2, wherein the plurality of first pixels comprises:
a first first sub-pixel configured to emit light of a first color;
a second first sub-pixel adjacent to the first first sub-pixel in a first direction, and configured to emit light of a second color;
a third first sub-pixel adjacent to the second first sub-pixel in a second direction crossing the first direction, and configured to emit light of a third color; and
a fourth first sub-pixel adjacent to the first first sub-pixel in the second direction, adjacent to the third first sub-pixel in the first direction, and configured to emit light of the second color, and
wherein the first photo sensor is adjacent to the first first sub-pixel in a first diagonal direction crossing the first direction and the second direction.

5. The display device of claim 4, wherein the plurality of second pixels comprises:
a first second sub-pixel configured to emit light of the first color;
a second second sub-pixel adjacent to the first second sub-pixel in the first direction, and configured to emit light of the second color;
a third second sub-pixel adjacent to the second second sub-pixel in the second direction, and configured to emit light of the third color; and
a fourth second sub-pixel adjacent to the first second sub-pixel in the second direction, adjacent to the third second sub-pixel in the first direction, and configured to emit light of the second color, and
wherein the second photo sensor is adjacent to the first second sub-pixel in the first diagonal direction.

6. The display device of claim 2, wherein each of the plurality of first pixels and the plurality of second pixels comprises a first sub-pixel, a second sub-pixel, a third sub-pixel, and a fourth sub-pixel.

7. The display device of claim 6, wherein:
the first sub-pixel is configured to emit red light;
the second sub-pixel and the fourth sub-pixel are configured to emit green light; and
the third sub-pixel is configured to emit blue light.

8. The display device of claim 7,
wherein the first sub-pixel and the third sub-pixel are alternately located along a first direction, the second sub-pixel and the fourth sub-pixel are alternately located along the first direction, and the first sub-pixel and the second sub-pixel are alternately located along a second direction crossing the first direction, and
wherein a maximum luminance of one of the plurality of second pixels is greater than a maximum luminance of one of the plurality of first pixels.

9. The display device of claim 8, wherein the maximum luminance of the one of the plurality of second pixels is greater than or equal to 1.5 times and less than or equal to 3 times the maximum luminance of the one of the plurality of first pixels.

10. The display device of claim 8, wherein a size of an area of the first sub-pixel of the plurality of second pixels is larger than a size of an area of the first sub-pixel of the plurality of first pixels.

11. The display device of claim 8, wherein a thickness of an emissive layer of the first sub-pixel of the plurality of second pixels is larger than a thickness of an emissive layer of the first sub-pixel of the plurality of first pixels.

12. The display device of claim 8, wherein an emissive layer of the first sub-pixel of the plurality of second pixels comprises a first luminous material, and an emissive layer of the first sub-pixel of the plurality of first pixels comprises a second luminous material, and
wherein the first luminous material has a higher luminous efficiency than that of the second luminous material.

13. The display device of claim 12, wherein the second luminous material has a higher color gamut than that of the first luminous material.

14. The display device of claim 2, wherein the second area is surrounded by the first area.

15. The display device of claim 4, wherein the plurality of second pixels comprises:
a first second sub-pixel configured to emit light of the first color;
a second second sub-pixel adjacent to the first second sub-pixel in the first direction, and configured to emit light of the second color; and
a third second sub-pixel adjacent to the second second sub-pixel in the second direction, and configured to emit light of the third color,
wherein the second photo sensor is adjacent to the first second sub-pixel in the second direction, and adjacent to the third second sub-pixel in the first direction.

16. The display device of claim 15, wherein a maximum luminance of one of the plurality of second pixels is greater than a maximum luminance of one of the plurality of first pixels.

17. A display device comprising:
a substrate;
light-receiving electrodes spaced from one another on the substrate;
pixel electrodes spaced from one another on the substrate, and spaced from the light-receiving electrodes;
a first emissive layer on a first pixel electrode from among the pixel electrodes;
a second emissive layer on a second pixel electrode from among the pixel electrodes;
a first photoelectric conversion layer on a first light-receiving electrode from among the light-receiving electrodes, and adjacent to the first emissive layer; and
a second photoelectric conversion layer on a second light-receiving electrode from among the light-receiving electrodes,
wherein a width of the second photoelectric conversion layer is different from a width of the first photoelectric conversion layer.

18. The display device of claim 17, wherein the second emissive layer is located closer to the second photoelectric conversion layer than the first photoelectric conversion layer, and
wherein the first emissive layer is located closer to the first photoelectric conversion layer than the second photoelectric conversion layer.

19. The display device of claim 18, wherein a maximum emission luminance of the second emissive layer is greater than that of the first emissive layer.

20. The display device of claim 18, wherein a width of the first emissive layer is greater than a width of the second emissive layer.
